(19) United States
(12) Patent Application Publication
(10) Pub. No.: US 2019/0191560 A1
(43) Pub. Date: Jun. 20, 2019

(54) FLEXIBLE CONDUCTIVE TRANSPARENT FILMS, ARTICLES AND METHODS OF MAKING SAME

(71) Applicants: The University of North Carolina at Chapel Hill, Chapel Hill, NC (US); EASTMAN CHEMICAL COMPANY, Kingsport, TN (US)

(72) Inventors: Rene Lopez, Chapel Hill, NC (US); Qian Dong, Carrboro, NC (US); Yukihiro Hara, Durham, NC (US); Patrick Daniel Puzzo, Johnson City, TN (US)

(21) Appl. No.: 16/322,070

(22) PCT Filed: Aug. 17, 2017
(86) PCT No.: PCT/US17/47425

§ 371 Date: Jan. 30, 2019

Related U.S. Application Data
(60) Provisional application No. 62/376,216, filed on Aug. 17, 2016.

(51) Int. Cl. H05K 1/03; G03F 7/00; G03F 7/20; G03F 7/40; H05K 1/02

(52) U.S. Cl. CPC H05K 1/0393; G03F 7/0002; G03F 7/2053; G03F 7/40; G02F 1/133305; H05K 1/028; H05K 2201/0108; H05K 2201/0326; H05K 1/0274

(57) ABSTRACT

The invention generally relates to articles and methods of making thereof. More specifically, articles comprising a substrate and a film deposited on the substrate, wherein the article is bendable to a bending diameter of about 3.8 mm or less without substantial structural failure of the film. Further, methods of making these articles are further disclosed. This abstract is intended as a scanning tool for purposes of searching in the particular art and is not intended to be limiting of the present invention.

### CROSS-REFERENCE TO RELATED APPLICATIONS

This Application claims the benefit of U.S. Provisional Application No. 62/376,216, filed on Aug. 17, 2016, which is incorporated herein by reference in its entirety.

### BACKGROUND

Recent advances in technologies for flexible optoelectronic and photonic devices used in liquid crystal displays (LCDs), organic light-emitting diodes (OLEDs), touch screens, thin-film transistors (TFTs), solar cells, e-papers, and sensors have necessitated fabrication of transparent electrodes on highly flexible and heat-sensitive substrates. These applications commonly require electrodes with very specific electrical conductivities and optical transparencies.

Transparent conducting oxides (TCOs) are electrically conductive materials with a comparably low absorption of light. Due to these unique properties, the TCOs are commonly used in optoelectronic devices such as solar cells, displays, optoelectrical interfaces, and circuits. However, the TCOs films suffer from one major drawback. Flexing a thin TCO film into a small curvature diameter, cracks the film due to imposed large strains and results in a failure of the article thereon the thin TCO film is deposited.

Thus, there is still a need for flexible transparent conducting oxides that are bendable to small curvatures without structural failure of the article. Still further, there is a need for methods of making flexible articles having high bendability, high transparency and conductivity.

### SUMMARY

In accordance with the purpose(s) of the invention, as embodied and broadly described herein, the invention, in one aspect, relates to an article comprising: a substrate; a film deposited on the substrate, wherein the article is bendable in at least one direction to a bending diameter of about 3.5 mm or less and wherein no substantial structural failure of the film is observed.

In still further aspects, described herein is an article comprising: a substrate; a film deposited on the substrate, wherein the article is bendable in at least one direction to a bending diameter of about 3.5 mm or less and wherein no substantial structural failure of the film is observed.

In yet other aspects, the invention relates to an article comprising a substrate comprising a plurality of spatially patterned periodic surface microstructures; and a transparent conductive film deposited on the substrate, wherein the film has at least one point of contact with at least one of the plurality of spatially patterned periodic surface microstructures.

Also disclosed are methods making an article comprising: depositing a film on a patterned substrate; wherein the article is bendable in at least one direction to a bending diameter of about 3.5 mm or less and wherein no substantial structural failure of the film is observed.

Even further disclosed herein is a method of making an article comprising: depositing a film on a patterned substrate; wherein the article is bendable in at least one direction to a bending diameter of about 3.8 mm or less and wherein no substantial structural failure of the film is observed.

Also disclosed herein are methods comprising depositing a transparent conductive film on a patterned substrate; wherein the patterned substrate comprises a plurality of spatially patterned periodic surface microstructures; and wherein the film has at least one point of contact with at least one of a plurality of spatially patterned periodic surface microstructures.

In yet further aspects, disclosed herein is an article comprising a polymeric substrate comprising a plurality of spatially patterned periodic surface microstructures, wherein the plurality of spatially patterned periodic surface microstructures forms a grating-like structure; an indium tin oxide film deposited on the polymeric substrate, wherein the film has at least one point of contact with at least one of a plurality of spatially patterned periodic surface microstructures, wherein the patterned periodic surface microstructures have a period A from about 100 nm to about 700 nm and amplitude from about to 0.05 times of a thickness of the film to about 10 times of a thickness of the film, and wherein the article is bendable in at least one direction to a bending diameter of about 3.8 mm or less and wherein no substantial structural failure of the article is observed.

In still further aspects, disclosed herein is an article comprising a polymeric substrate comprising a plurality of spatially patterned periodic surface microstructures, wherein the plurality of spatially patterned periodic surface microstructures forms a grating-like structure; an indium tin oxide film deposited on the polymeric substrate, wherein the film has at least one point of contact with at least one of a plurality of spatially patterned periodic surface microstructures, wherein the patterned periodic surface microstructures have a period A from about 100 nm to about 700 nm and amplitude from about to 0.05 times of a thickness of the film to about 10 times of a thickness of the film, and wherein the article is bendable in at least one direction to a bending diameter of about 3.8 mm or less and wherein no substantial structural failure of the article is observed.

In still further aspects, disclosed herein is a method comprising forming a patterned polymeric substrate comprising a plurality of spatially patterned periodic surface microstructures; and depositing an indium tin oxide film on the substrate; wherein the plurality of spatially patterned periodic surface microstructures forms a grating-like structure having a period A from about 100 nm to about 700 nm and amplitude from about to 0.05 times of a thickness of the film to about 10 times of a thickness of the film; wherein the film has at least one point of contact with at least one of a plurality of spatially patterned periodic microstructures; and wherein the article is bendable in at least one direction to a bending diameter of about 3.8 mm or less and wherein no substantial structural failure of the article is observed.

In still further aspects, disclosed herein is method comprising forming a patterned polymeric substrate comprising a plurality of spatially patterned periodic surface microstructures; and depositing an indium tin oxide film on the substrate; wherein the plurality of spatially patterned periodic surface microstructures forms a grating-like structure having a period A from about 100 nm to about 700 nm and amplitude from about to 0.05 times of a thickness of the film to about 10 times of a thickness of the film; wherein the film has at least one point of contact with at least one of a plurality of spatially patterned periodic microstructures; and wherein the article is bendable in at least one direction to a bending diameter of about 3.8 mm or less and wherein no substantial structural failure of the article is observed. In still further aspects, disclosed herein is an article comprising a polymeric substrate comprising a plurality of spatially patterned periodic surface microstructures, wherein the plurality of spatially patterned periodic surface microstructures forms a dot shaped microstructures comprising a circular, a square, a hexagonal array microstructures, or a combination thereof; an indium tin oxide film deposited on the polymeric substrate, wherein the film has at least one point of contact with at least one of a plurality of spatially patterned periodic surface microstructures, wherein the patterned periodic surface microstructures have a period A from about 100 nm to about 700 nm and amplitude from about to 0.05 times of a thickness of the film to about 10 times of a thickness of the film, and wherein the article is bendable in at least one direction to a bending diameter of about 3.8 mm or less and wherein no substantial structural failure of the article is observed.

In yet other aspects, disclosed herein is a method comprising: forming a patterned polymeric substrate comprising a plurality of spatially patterned periodic surface microstructures; and depositing an indium tin oxide film on the substrate; wherein the plurality of spatially patterned periodic surface microstructures forms a dot shaped microstructures comprising a circular, a square, a hexagonal array microstructures, or a combination thereof, and wherein the plurality of spatially patterned periodic surface microstructures has a period A from about 10 nm to about 700 nm and amplitude from about to 0.05 times of a thickness of the film to about 10 times of a thickness of the film; wherein the film has at least one point of contact with at least one of a plurality of spatially patterned periodic microstructures; and wherein the article is bendable in at least one direction to a bending diameter of about 3.8 mm or less and wherein no substantial structural failure of the article is observed.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

### BRIEF DESCRIPTION OF THE DRAWINGS

The accompanying figures, which are incorporated in and constitute a part of this specification, illustrate several aspects and together with the description serve to explain the principles of the invention.

FIG. 1 depicts (a) a scanning electron microscopy (SEM) image of a control article comprising a film deposited on a flat substrate; (b) a plot showing a change in resistance of an indium tin oxide film deposited on a flat 100 μm PET substrate as a function of bending; (c) a plot showing different bending diameters resulting in a crack point as a function of a substrate thickness.

FIG. 2 depicts a strain of a film at a film rupture as a function of a substrate thickness.

FIG. 3 shows a scanning electron microscopy (SEM) image of an exemplary patterned article A.

FIG. 4 depicts an exemplary change in measured resistance as a function of bending of an exemplary patterned article A.

FIG. 5 depicts a scanning electron microscopy (SEM) image of an exemplary patterned article B.

FIG. 6 depicts an exemplary change in measured resistance as a function of bending of an exemplary patterned article B.

FIG. 7 depicts a strain of a film at a film rupture as a function of a substrate thickness for a control sample and an inventive sample.

FIG. 8 depicts photographic images of exemplary articles comprising a substrate having a plurality of spatially patterned periodic microstructures with a period of (a) 560 nm and (b) 285 nm.

FIG. 9 depicts a scanning electron microscopy (SEM) image of a patterned substrate (a) top view of the surface; (b) cross-section image.

FIG. 10 depicts a transmittance of an exemplary indium tin oxide (ITO) film deposited on an exemplary patterned PET substrate having a plurality of spatially patterned periodic microstructures with a period 285 nm (dashed line) and 560 nm (solid line).

FIG. 11 depicts a bending test performed on an exemplary article comprising an exemplary indium tin oxide (ITO) film deposited on an exemplary patterned PET substrate.

FIG. 12 depicts a comparative transmittance test of 285 nm period, 1:1 patterned PET with ITO; 560 nm period, 1:1 patterned PET with ITO; flat (non-patterned) PET with 1:1 photoresist; flat (non-patterned PET) with deposited ITO (OC 100 5 mil). As defined herein, the term “1:1 patterned PET” refers to a photoresist diluted with a solvent in a ratio of 1:1. In certain aspects, 285 nm period pattern is also referred as a “new pattern,” while 560 nm period pattern is also referred as an “old pattern.”

FIG. 13 depicts a comparative transmittance test of Eastman's flat PET with ITO vs. 1:1 patterned PET with ITO (a period of 285 nm). OCXX is a Eastman product code name that represents the sheet resistance of the PET films with ITO film in ohm/square; and mil is the unit of thickness of PET films, 1 mil=25.4 μm.

FIG. 14 depicts the sheet resistance increase of the ITO film on an exemplary two (2) directional hexagonal periodic grating patterned PET substrate as a function of diameter of curvature (a) along one pair of parallel edges and then (b) along the other pair of parallel edges. During each cycle, the minimum bending diameter of curvature was kept at 3.8 mm.

FIG. 15 depicts an SEM surface image of the morphology of the exemplary two (2) directional hexagonal ITO periodic grating patterns on the surfaces of the polymer substrates.

FIG. 16 depicts a transmittance comparison of the exemplary indium tin oxide (ITO) film deposited on the exemplary two (2) directional-hexagonal patterned PET substrate with a period of 235 nm and standard commercial ITO continuous films.

FIG. 17 depicts a topography image of a two directional square microlens array with an edge period of 530 nm and a diagonal period of 756 nm.

FIG. 18 depicts a topography image of a two directional hexagonal array with features heights in the range of 30-50 nm, and a period of 290 nm.

FIG. 19 depicts the schematic diagram (a) and corresponding photograph (b) of the exemplary bending system.

FIG. 20 depicts a schematic of fabrication of the exemplary ITO periodic grating pattern with LIL process.

FIG. 21 depicts an SEM surface image (a) and cross-section image (b) of the morphology of the exemplary ITO periodic grating patterns on the surfaces of the polymer substrates.

FIG. 22 depicts a comparison of the sheet resistance (a) and relative resistance increase (b) between the exemplary ITO periodic grating patterns on the surfaces of the polymer substrates as a function of diameter of curvature during the bending test. Insets show the magnified scale.

FIG. 23 depicts the sheet resistance and relative resistance increase of the exemplary ITO films on periodic grating pattern on the exemplary PET substrate as a function of diameter of curvature during the bending test. During each cycle, the minimum bending diameter of curvature was kept at 3.2 mm. And the specimen experienced 50 cycles of the reversible bending test.

FIG. 24 depicts a tensile stress simulation of continuous and exemplary patterned ITO films with critical strain.

FIG. 25 depicts a comparison of (a) Specular transmittance of ITO with PET substrate and (b) local transmittance of ITO only in the form of ITO continuous film and ITO nanopattern.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DESCRIPTION

The present invention can be understood more readily by reference to the following detailed description of the invention and the Examples included therein.

Before the present compounds, compositions, articles, systems, devices, and/or methods are disclosed and described, it is to be understood that they are not limited to specific synthetic methods unless otherwise specified, or to particular reagents unless otherwise specified, as such may, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

Throughout this application, various publications are referenced. The disclosures of these publications in their entireties are hereby incorporated by reference into this application in order to more fully describe the state of the art to which this pertains. The references disclosed are also individually and specifically incorporated by reference herein for the material contained in them that is discussed in the sentence in which the reference is relied upon. Nothing herein is to be construed as an admission that the present invention is not entitled to antedate such publication by virtue of prior invention. Further, the dates of publication provided herein may be different from the actual publication dates, which can require independent confirmation.

### A. DEFINITIONS

As used herein, nomenclature for compounds, including organic compounds, can be given using common names, IUPAC, IUBMB, or CAS recommendations for nomenclature.

As used in the specification and the appended claims, the singular forms “a,” “an” and “the” include plural referents unless the context clearly dictates otherwise. Thus, for example, reference to “a substrate,” “a film,” or “an article” includes two or more such substrates, films, articles, and the like.

Ranges can be expressed herein as from “about” one particular value, and/or to “about” another particular value. When such a range is expressed, a further aspect includes from the one particular value and/or to the other particular value. Similarly, when values are expressed as approximations, by use of the antecedent “about,” it will be understood that the particular value forms a further aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

All percentages, ratios and proportions herein are by weight, unless otherwise specified. All temperatures are in degrees Celsius (° C.) unless otherwise specified.

Throughout the description and claims of this specification the word “comprise” and other forms of the word, such as “comprising” and “comprises,” means including but not limited to, and is not intended to exclude, for example, other additives, components, integers, or steps.

As used herein, the term “substantially” means that the subsequently described event or circumstance completely occurs or that the subsequently described event or circumstance generally, typically, or approximately occurs. For example, when the specification discloses that substantially no diffractive effects are observed, a person skilled in the relevant art would readily understand that the diffractive effect does not have to be fully absent. Rather, this term conveys to a person skilled in the relevant art that the diffractive effect can be present to an extent that does not hinder desirable results or causes adverse effects.

As used herein, the term “transparent conductive oxide” generally refers to a film comprising a metal or metal combinations, A, combined with a nonmetal part, B, comprising of oxygen, and having a generic formula A_{y}B_{z}. It is understood that A_{y}B_{z} compounds have semiconductor properties and various optoelectrical characteristics. In some aspects, the optoelectrical characteristics can be changed by doping, A_{y}B_{z}:D (D=dopant), with metals, metalloids, or nonmetals.

As used herein, the term “transparent conductive film” generally refers to films comprising transparent conductive oxides, conductive polymers, metal grids, carbon nanotube (CNT), graphene, nanowire meshes, ultra-thin metal films, and the like.

As used herein, the terms “optional” or “optionally” means that the subsequently described event or circumstance can or cannot occur, and that the description includes instances where said event or circumstance occurs and instances where it does not.

As used herein, the term “polymer” refers to a relatively high molecular weight organic compound, natural or synthetic, whose structure can be represented by a repeated small unit, the monomer (e.g., polyethylene, polypropylene, rubber, or cellulose). Synthetic polymers are typically formed by addition or condensation polymerization of monomers.

As used herein, the term “copolymer” refers to a polymer formed from two or more different repeating units (monomer residues). By way of example and without limitation, a copolymer can be an alternating copolymer, a random copolymer, a block copolymer, or a graft copolymer. It is also contemplated that, in certain aspects, various block segments of a block copolymer can themselves comprise copolymers.

As used herein, the term “oligomer” refers to a relatively low molecular weight polymer in which the number of repeating units is between two and ten, for example, from two to eight, from two to six, or from two to four. In one aspect, a collection of oligomers can have an average number of repeating units of from about two to about ten, for example, from about two to about eight, from about two to about six, or from about two to about four.

As used herein, the term or phrase “effective,” “effective amount,” or “conditions effective to” refers to such amount or condition that is capable of performing the function or property for which an effective amount is expressed. As will be pointed out below, the exact amount or particular condition required will vary from one aspect to another, depending on recognized variables such as the materials employed and the processing conditions observed. Thus, it is not always possible to specify an exact “effective amount” or “condition effective to.” However, it should be understood that an appropriate effective amount will be readily determined by one of ordinary skill in the art using only routine experimentation.

As used herein, the term “grating-like structure” refers to a structure having a fixed frame of a plurality of parallel or crossed bars or the like, having a specific size covering a surface of a substrate. It is understood that a size of each of the plurality of parallel or crossed bars can be same or different. It is further understood that the size of the each of the plurality of parallel or crossed bars can be predetermined by one of ordinary skill in the art based on a specific application. It is further understood that a number of bars present in the plurality of parallel or crossed bars can be predetermined by one of ordinary skill in the art based on a specific application.

As used herein, the term “microstructure” refers to structures having a size from about 0.1 nm to about 100 μm, including exemplary values of about 0.5 nm, about 1 nm, about 5 nm, about 10 nm, about 50 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 1 μm, about 5 μm, about 10 μm, about 50 μm, and about 100 μm.

As used herein the term “transparent film” refers to a film having the property of transmitting light without substantial absorbing and scattering. For example, the film can have an absorbance of less than about 40%, less than about 35%, less than about 30%, less than about 25%, less than about 20%, less than about 15%, less than about 10%, less than about 5%, less than about 1%.

As used herein the term “conductive film” refers to electrically conductive films.

As used herein the term “sheet resistance” refers to a measure of resistance of thin films that are substantially uniform in thickness. In some aspects, the sheet resistance can be used to evaluate film conductivity with knowledge of the film thickness.

As used herein, the term “derivative” refers to a compound having a structure derived from the structure of a parent compound (e.g., a compound disclosed herein) and whose structure is sufficiently similar to those disclosed herein and based upon that similarity, would be expected by one skilled in the art to exhibit the same or similar activities and utilities as the claimed compounds, or to induce, as a precursor, the same or similar activities and utilities as the claimed compounds. Exemplary derivatives include salts, esters, amides, salts of esters or amides, and N-oxides of a parent compound.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

The term “aliphatic” or “aliphatic group,” as used herein, denotes a hydrocarbon moiety that may be straight-chain (i.e., unbranched), branched, or cyclic (including fused, bridging, and spirofused polycyclic) and may be completely saturated or may contain one or more units of unsaturation, but which is not aromatic. Unless otherwise specified, aliphatic groups contain 1-20 carbon atoms. Aliphatic groups include, but are not limited to, linear or branched, alkyl, alkenyl, and alkynyl groups, and hybrids thereof such as (cycloalkyl)alkyl, (cycloalkenyl)alkyl or (cycloalkyl)alkenyl.

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

As defined herein, the term “polyolefin” refers to any class of polymers produced from a simple olefin (also called an alkene with the general formula CₙH₂ₙ) as a monomer. In some aspects, the polyolefins which can be used as a polymeric substrate include, but are not limited to, polyethylene, polypropylene, both homopolymer and copolymers, poly(1-butene), poly(3-methyl-1-butene), poly(4-methyl-1-pentene) and the like, as well as combinations or mixtures of two or more of the foregoing.

The term “polyamide,” as utilized herein, is defined to be any long-chain polymer in which the linking functional groups are amide (—CO—NH—) linkages. The term polyamide is further defined to include copolymers, terpolymers and the like as well as homopolymers and also includes blends of two or more polyamides. In some aspects, polyamide based polymeric substrate can comprise one or more of nylon 6, nylon 66, nylon 10, nylon 612, nylon 12, nylon 11, or any combination thereof.

The term “polyester polymer” as utilized herein, refers to a polymer comprising a long-chain synthetic polymer composed of at least 85% by weight of an ester of a substituted aromatic carboxylic acid, including but not restricted to substituted terephthalic units, p(-R—O—CO—C₆H₄—CO—O—)ₓ and parasubstituted hydroxy-benzoate units, p(-R—O—CO—C₆H₄—O)ₓ. In some aspects, the polyester substrate comprise polyethylene terephthalate (PET) homopolymers and copolymers, polybutylene terephthalate (PBT) homopolymers and copolymers, and the like, including those that contain comonomers such as cyclohexanedimethanol, cyclohexanedicarboxylic acid, and the like.

The term “polystyrene” refers to any class of polymers produced from a simple styrene monomer. Polystyrenes described herein can include both syndiotactic and atactic polystyrenes. Polystyrenes described herein can also comprise expanded polystyrenes and extruded polystyrenes. In some aspects, the polystyrenes described herein can comprise copolymers. In exemplary aspects, styrene monomer can be polymerized with a different monomer to form a graft polymer. Examples of these graft polymers include but are not limited to styrene-butadiene polymer, acrylonitrile-butadiene-styrene, and the like.

The term “polyimide” or “PI” as referred herein can be used interchangeably and relate to a polymer comprising imide monomers.

The terms “polyetherimide” or “PEI” as referred herein can be used interchangeably and relate to a polymer containing cyclic imides and ether units in the backbone. PEI is categorized as a special class of polyimide (PI) which is a condensation polymer derived from bifunctional carboxylic anhydrides and primary diamines.

The term “polyetherketone” as referred herein relates to a family of high-performance thermoplastic polymers, consisting of an aromatic backbone molecular chain interconnected by ketone and ether functional groups.

The term “cellulose” as referred herein refers to a family of organic compounds with the formula C₆H₁₀O₅, polysaccharides consisting of a linear chain of several hundred to many thousands of β(1→4) linked D-glucose units. In certain aspects, the hydroxyl groups (—OH) of cellulose can be partially of fully reacted with various reagents to form derivatives such as cellulose esters and cellulose ethers.

As disclosed herein, the term “structural failure of the film” refers to any change in a structure of the film that causes the film to lose the desired properties. For example and without limitation, structural failure of the film includes cracking of the film, rupture of the film, pilling of the film, peeling of the film and the like.

As disclosed herein, the terms “bendable in at least one direction” or “bendable in at least one dimension” can be used interchangeably and refer to an ability of the film to be bended to a specified bending diameter in at least one plane. In some aspects, the articles described herein are bendable in at least two directions or bendable in at least two dimensions. In these aspects, the articles can be bended to a specified bending diameter over at least two different planes.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; and the number or type of embodiments described in the specification.

Disclosed are the components to be used to prepare the compositions of the invention as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

It is understood that the compositions disclosed herein have certain functions. Disclosed herein are certain structural requirements for performing the disclosed functions, and it is understood that there are a variety of structures that can perform the same function that are related to the disclosed structures, and that these structures will typically achieve the same result.

### B. ARTICLES

In certain aspects, disclosed herein is an article comprising: a substrate; a film deposited on the substrate, wherein the article is bendable in at least one direction to a bending diameter of about 3.5 mm or less and wherein no substantial structural failure of the film is observed.

In still further aspects, disclosed herein is an article comprising: a substrate; a film deposited on the substrate, wherein the article is bendable in at least one direction to a bending diameter of about 3.8 mm or less and wherein no substantial structural failure of the film is observed

In still further aspects, the article disclosed herein can be any article known in the art. In yet other aspects, the article is a flexible article. In some aspects, the article is not a film. In other aspects, the articles can comprise, for example and without limitation, electronic devices, flexible sensors, solar cells, smart windows, touch screen panels, pen entry devices, watches, e-readers, and the like.

In yet other aspects, disclosed herein is an article comprising: a substrate comprising a plurality of spatially patterned periodic surface microstructures; and a transparent conductive film deposited on the substrate; wherein the film has at least one point of contact with at least one of the plurality of spatially patterned periodic surface microstructures.

In some aspects, the article is bendable in at least one direction to a bending diameter of about 4.0 mm or less and wherein no substantial structural failure of the article is observed. In still further aspects, the articles is bendable to a bending diameter of about 3.8 mm or less, or about 3.7 mm or less, or about 3.6 mm or less, or about 3.5 mm or less, or about 3.4 mm or less, or about 3.3 mm or less, or about 3.2 mm or less, or about 3.1 mm or less, or about 3.0 mm or less.

In still further aspects, the article is bendable in at least one direction to a bending diameter of about 3.5 mm or less and wherein no substantial structural failure of the article is observed. In still further aspects, the articles is bendable to a bending diameter of about 3 mm or less, of about 2.5 mm or less, or about 2 mm or less. In yet other aspects, the article is bendable in more than one direction.

In still further aspects, the article described herein is bendable in at least two directions to a bending diameter of about 4.0 mm or less and wherein no substantial structural failure of the article is observed. In still further aspects, the articles is bendable to a bending diameter of about 3.8 mm or less, or about 3.7 mm or less, or about 3.6 mm or less, or about 3.5 mm or less, or about 3.4 mm or less, or about 3.3 mm or less, or about 3.2 mm or less, or about 3.1 mm or less, or about 3.0 mm or less. In still further aspects, the article described herein is bendable in at least two directions to a bending diameter of about 3.5 mm or less and wherein no substantial structural failure of the article is observed. In still further aspects, the articles is bendable to a bending diameter of about 3 mm or less, of about 2.5 mm or less, or about 2 mm or less.

In still further aspects, the article described herein exhibits substantially no diffractive effects. In some aspects, the article described herein has a light transmission equal to or greater than about 65%, about 67%, about 70%, about 73%, about 75%, about 77%, about 80%, about 83%, about 85%, about 87%, or about 90% in a wavelength range from about 400 nm to about 900 nm. In yet other aspects, the art article described herein has a light transmission equal to or greater than about 90%, equal to or greater than 91%, equal to or greater than 92%, equal to or greater than 93%, equal to or greater than 94%, equal to or greater than 95%, equal to or greater than 96%, equal to or greater than 97%, equal to or greater than 98%, equal to or greater than 99% in a wavelength range from about 300 nm to about 800 nm. In still further aspects, the article described herein is substantially transparent in a wavelength range from about 400 nm to about 900 nm.

In yet other aspects, the article described herein exhibits haze of less than about 1%, less than about 0.8%, less than about 0.5%, less than about 0.3%, or less than about 0.1%. In yet other aspects, the articles are substantially haze free. In certain aspects, the article described herein exhibits b*(color) value of less than about 2, less than about 1.8, less than about 1.5, less than about 1.3, less than about 1, less than about 0.8, or less than about 0.5.

In certain aspects, the article described herein article has resistivity equal to or less than about 1×10⁻⁴ Ohm×cm, equal to or less than about 0.8×10⁻⁴ Ohm×cm, equal to or less than about 0.5×10⁻⁴ Ohm×cm, equal to or less than about 0.3×10⁻⁴ Ohm×cm, or equal to or less than about 1×10⁻⁵ Ohm×cm, equal to or less than about 0.8×10⁻⁵ Ohm×cm, or equal to or less than about 0.5×10⁻⁵ Ohm×cm. In still further aspects, the article has a sheet resistance from about 0.01 to about 10,000 Ohm/Sq, including exemplary values of about 0.1 Ohm/Sq, about 0.5 Ohm/Sq, about 1 Ohm/Sq, about 10 Ohm/Sq, about 50 Ohm/Sq, about 100 Ohm/Sq, about 200 Ohm/Sq, about 300 Ohm/Sq, about 400 Ohm/Sq, about 500 Ohm/Sq, about 600 Ohm/Sq, about 700 Ohm/Sq, about 800 Ohm/Sq, about 900 Ohm/Sq, about 1,000 Ohm/Sq, about 1,500 Ohm/Sq, about 2,000 Ohm/Sq, about 2,500 Ohm/Sq, about 3,000 Ohm/Sq, about 3,500 Ohm/Sq, about 4,000 Ohm/Sq, about 4,500 Ohm/Sq, about 5,000 Ohm/Sq, about 5,500 Ohm/Sq, about 6,000 Ohm/Sq, about 6,500 Ohm/Sq, about 7,000 Ohm/Sq, about 7,500 Ohm/Sq, about 8,000 Ohm/Sq, about 8,500 Ohm/Sq, about 9,000 Ohm/Sq, and about 9,500 Ohm/Sq.

In still further aspects, the bendable article described herein can have a resistivity ratio R_{final}/Rᵢₙᵢₜᵢₐₗ is 1.0<R_{final}/Rᵢₙᵢₜᵢₐₗ<1.1, wherein Rᵢₙᵢₜᵢₐₗ is resistivity of the article prior to the bending and R_{final} is the resistivity of the bended article.

In still further aspects, described herein, is the article that is bendable and is capable of passing a mandrel test of 3 mm rod for at least about 10 cycles, at least about 20 cycles, at least about 30 cycles, at least about 40 cycles, about 50 cycles, at least about 60 cycles, at least about 70 cycles, at least about 80 cycles, at least about 90 cycles, at least about 100 cycles, at least 150 cycles, at least 200 cycles, or at least 300 cycles. In yet other aspects, the article is bendable and is capable of passing a mandrel test of 3 mm rod for about 10 to about 500 cycles, including exemplary values of about 20 cycles, about 30 cycles, about 40 cycles, about 50 cycles, about 60 cycles, about 70 cycles, about 80 cycles, about 90 cycles, about 100 cycles, about 120 cycles, about 150 cycles, about 170 cycles, about 200 cycles, about 250 cycles, about 300 cycles, about 350 cycles, about 400 cycles, and about 450 cycles. It is further understood that the articles can be bendable and is capable of passing a mandrel test of 3 mm rod for any number of cycles between any foregoing numbers of cycles.

Disclosed herein an article comprising a substrate. In yet other aspects, the substrate can comprise any substrates known in the art. In certain aspects, the substrate can comprise a glass, a metal, a metal alloy, a metal oxide, a polymer, and the like. In yet other aspects, the substrate is a flexible substrate. In still further aspects, the substrate is a polymeric substrate. In the aspects, wherein the substrate is a polymer, the polymeric substrate can comprise any known in the art polymers having desirable properties for a specific article's application. It is further understood that in some aspects, a specific polymeric substrate can be chosen by one of ordinary skill in the art based on the desired functionalities and properties of the disclosed article. In still further aspects, the polymeric substrate is a flexible substrate.

In one aspect, the substrate can comprise a thermoplastic polymer. In yet another aspect, the substrate can comprise a thermosetting polymer. In a still further aspect, the substrate can comprise a blend of thermoplastic and thermosetting polymers. It is further understood that any thermoplastic polymer can also be a blend of polymers, copolymers, terpolymers, or combinations including at least one of the foregoing organic polymers. In one aspect, examples of the organic polymer are polyethylene (PE), including high-density polyethylene (HDPE), linear low-density polyethylene (LLDPE), low-density polyethylene (LDPE), mid-density polyethylene (MDPE), glycidyl methacrylate modified polyethylene, maleic anhydride functionalized polyethylene, maleic anhydride functionalized elastomeric ethylene copolymers, ethylene-butene copolymers, ethylene-octene copolymers, ethylene-acrylate copolymers, such as ethylene-methyl acrylate, ethylene-ethyl acrylate, and ethylene butyl acrylate copolymers, glycidyl methacrylate functionalized ethylene-acrylate terpolymers, anhydride functionalized ethylene-acrylate polymers, anhydride functionalized ethylene-octene and anhydride functionalized ethylene-butene copolymers, polypropylene (PP), maleic anhydride functionalized polypropylene, glycidyl methacrylate modified polypropylene, polyacetals, polyacrylics, polycarbonates, polystyrenes, polyesters, polyamides, amorphous polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyoxadiazoles, polybenzothiazinophenothiazines, polybenzothiazoles, polypyrazinoquinoxalines, polypyromellitimides, polyquinoxalines, polybenzimidazoles, polyoxindoles, polyoxoisoindolines, polyoxymethylenes, polydioxoisoindolines, polytriazines, polypyridazines, polypiperazines, polypyridines, polypiperidines, polytriazoles, polypyrazoles, polypyrrolidines, polycarboranes, polyoxabicyclononanes, polydibenzofurans, polyphthalides, polyacetals, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polysilazanes, polyethylenenaphthalenes, polyurethanes, cellulose, cellulose ethers, cellulose esters, or the like, or a combination including at least one of the foregoing organic polymers.

In some exemplary aspects, the polymeric substrate can comprises a polyester, a cellulose ester, a polyolefin, a polyamide, a polyimide, a polystyrene, a polyetherimide, a polyethersulfone, a polyetherketone, a polyethylene naphthalene, a polycarbonate, a cyclic olefin polymer, or any combination thereof.

In still further aspects, the polymeric substrate comprises a polyester, a copolyester, a cellulose ester, a polyolefin, a polyamide, a polyimide, a polystyrene, a polystyrene copolymer, a styrene acrylonitrile copolymer, an acrylontirile butadiene styrene copolymer, a nylon, a poly(methylmethacrylate), an acrylic copolymer, polyphenylene oxide, a poly(phenylene oxide)/polystyrene blend, polyphenylene sulfides polyetherimide, a polyethersulfone, polyphenylene sulfide/sulfones, polysulfones, a polyetherketone, a polyethylene naphthalene, polycarbonate, poly(ester-carbonates), a cyclic olefin polymer, or any combination thereof.

In yet other aspects, the polymeric substrate comprises polyethylene-2,6-naphthalate (PEN), polyethylene terephthalate (PET), polyimide polymer (PI), polycarbonate, cellulose triacetate (TAC), polypropylene, or a combination thereof

In some aspects, the substrate comprises polyolefins. In some aspects, the polyolefins can comprise homogeneously branched and linear polyethylenes. Homogeneously branched ethylene polymer is homogeneous ethylene polymer that refers to an ethylene polymer in which the monomer or comonomer is randomly distributed within a given polymer or interpolymer molecule and wherein substantially all of the polymer or interpolymer molecules have substantially the same ethylene to comonomer molar ratio with that polymer or interpolymer.

It is understood that the terms “homogeneous linearly branched ethylene polymer” or “homogeneously branched linear ethylene/α-olefin polymer” do not refer to high pressure branched polyethylene which is known to those skilled in the art to have numerous long chain branches. The term “homogeneous linear ethylene polymer” generically refers to both linear ethylene homopolymers and to linear ethylene/α-olefin interpolymers. A linear ethylene/α-olefin interpolymer possesses short chain branching and the α-olefin is typically at least one C₃-C₂₀ α-olefin (e.g., propylene, 1-butene, 1-pentene, 4-methyl-1-pentene, 1-hexene, and 1-octene). In other aspects the polyethylenes that are suitable for use in the present invention are interpolymers of ethylene with at least one C₃-C₂₀ α-olefin and/or C₄-C₁₈ diolefin. Copolymers of ethylene and α-olefin of C₃-C₂₀ carbon atoms can be used.

The term “interpolymer” is used herein to indicate a copolymer, or a terpolymer, or the like, where at least one other comonomer is polymerized with ethylene to make the interpolymer. Suitable unsaturated comonomers useful for polymerizing with ethylene include, for example, ethylenically unsaturated monomers, conjugated or non-conjugated dienes, polyenes, etc. Examples of such comonomers include C₃-C₂₀ α-olefins as propylene, isobutylene, 1-butene, 1-hexene, 4-methyl-1-pentene, 1-heptene, 1-octene, 1-nonene, 1-decene, 1,9-decadiene and the like. Other suitable monomers include styrene, halo- or alkyl-substituted styrenes, tetrafluoroethylene, vinylbenzocyclobutane, 1,4-hexadiene, 1,7-octadiene, and cycloalkenes, e.g., cyclopentene, cyclohexene and cyclooctene.

In yet other aspects, the polyolefins can comprise heterogeneously branched ethylene polymers having a distribution of branching different from and broader that the homogeneous branching ethylene/α-olefin interpolymer at similar molecular weight. In further aspects, the “heterogeneous” and “heterogeneously branched” mean that the ethylene polymer is characterized as a mixture of interpolymer molecules having various ethylene to comonomer molar ratios.

In yet other aspects, the polyolefins can comprise ultra-low density polyethylene (“ULDPE”), very low density polyethylene (“VLDPE”), linear low density polyethylene (“LLDPE”) medium density polyethylene (“MDPE”) or high density polyethylene (“HDPE”).

In still other aspects, the polyolefin based polymeric substrate can comprise free-radical initiated highly branched high pressure low density ethylene homopolymer and ethylene interpolymers such as, for example, ethylene-acrylic acid (EAA) copolymers and ethylene-vinyl acetate (EVA) copolymers, in that substantially linear ethylene polymers do not have equivalent degrees of long chain branching and are made using single site catalyst systems rather than free-radical peroxide catalyst systems.

In one aspect, the polyolefins include, but are not limited to, polyethylene, polypropylene, both homopolymer and copolymers, poly(1-butene), poly(3-methyl-1-butene), poly(4-methyl-1-pentene) and the like as well as combinations or mixtures of two or more of the foregoing. In yet other aspects, the polyolefins can comprise polypropylene (PP), low-density polyethylene (LDPE), high-density polyethylene (HDPE), or any combination thereof.

In certain aspects, the substrate can comprise polyamides. In some aspects, polyamides can comprise one or more of nylon 6, nylon 66, nylon 10, nylon 612, nylon 12, nylon 11, or any combinations thereof. In yet other aspects, the substrate can comprise amorphous polyamides, for example, commercially available TRANSPHAN® material produced from amorphous polyamide, a special thermoplastic raw material with a balanced ratio of polar and nonpolar components; or commercially available SELAR® material.

In still further aspects, the substrate can comprise polyesters. In certain aspects, the polyesters can comprise terephthalate based esters. In yet other aspects, the polyester can comprise polyethylene terephthalate (PET) homopolymers and copolymers, polypropylene terephthalate (PPT/PTT) homopolymers and copolymers, polybutylene terephthalate (PBT) homopolymers and copolymers, and the like, including those that contain comonomers such as cyclohexanedimethanol, cyclohexanedicarboxylic acid, and the like. In further aspects, the polyester can comprise polyethylene terephthalate glycol modified (PETG). In yet other aspects, the polyester can comprise a crystalline polyethylene terephthalate (CPET). In still further aspects, the polyester can comprise a polycyclohexylenedimethylene terephthalate (PCT) or glycol modified polycyclohexylenedimethylene terephthalate (PCTG). In still further aspects, the polyester can comprise polyethylene terephthalate, polypropylene terephthalate, polybutylene terephthalate, or any combinations thereof

In certain aspects, the polymeric substrate can comprise a polystyrene polymer. In yet other aspects, the polystyrenes described herein can be formed from a vinyl aromatic monomer having the formula: H₂C═CR—Ar—, wherein R is hydrogen or an alkyl group having from 1 to 4 carbon atoms and Ar is an aromatic group (including various alkyl and halo-ring-substituted aromatic units) having from about 6 to about 10 carbon atoms. In some exemplary aspects, the monomers can include, without limitation, styrene, alpha-methylstyrene, ortho-methylstyrene, meta-methylstyrene, para-methylstyrene, para-ethylstyrene, isopropenyltoluene, isopropenylnaphthalene, vinyl toluene, vinyl naphthalene, vinyl biphenyl, vinyl anthracene, the dimethylstyrenes, t-butylstyrene, the several chlorostyrenes (such as the mono- and dichloro-variants), and the several bromostyrenes (such as the mono-, dibromo- and tribromo-variants), and the like. According to one aspect of the present invention, the monomer is styrene.

In still further aspects, the substrate can comprise polyketones. In some aspects polyketones can comprise a polyaryletherketone. In still further aspects, polyaryletherketones can comprise any polyaryletherketone material or mixture of materials, for example, polyetheretherketone (PEEK), polyetherketone (PEK), polyetherketoneketone (PEKK), polyetherketoneetherketoneketone (PEKEKK), or polyetheretherketoneketone (PEEKK), or a combination thereof. In certain aspects, polyetheretherketone can include polyetheretherketone co-polymers. In another aspect, the substrate can comprise polyetheretherketone homopolymer.

In some aspects, the substrate can comprise polyetherimides. The polyetherimide can be selected from (i) polyetherimide homopolymers, e.g., polyetherimides, (ii) polyetherimide co-polymers, e.g., polyetherimidesulfones, and (iii) combinations thereof. Polyetherimides are known polymers and are sold by SABIC under the ULTEM®*, EXTEM®*, and Siltem* brands (Trademark of SABIC Innovative Plastics IP B.V.).

In still further aspects, the substrate can comprise cellulose esters. In certain aspects, the cellulose esters comprise cellulose acetate butyrate, cellulose acetate propionate, cellulose acetate, cellulose triacetate, cellulose tripropionate, or a combination thereof

In certain aspects, the polymeric substrate has a thickness from about 50 μm to about 500 μm, including exemplary values of about 100 μm, about 130 μm, about 150 μm, about 180 μm, about 200 μm, about 230 μm, about 250 μm, about 280 μm, about 300 μm, about 320 μm, about 350 μm, about 380 μm, about 400 μm, about 430 μm, and about 450 μm. In still further aspects, it is understood that the polymeric substrate can have any thickness that allows a substantial flexibility of the substrate.

In some aspects, the polymeric substrate can comprise a plurality of spatially patterned random surface microstructures. In still further aspects, the polymeric substrate described herein can comprise a plurality of spatially patterned periodic surface microstructures. In certain aspects, the periodic microstructures can comprise any shape or form known in the art. In yet other aspects, the periodic microstructures can comprise features of any shape or symmetry. In still further aspects, the periodic microstructures present on the substrate can have the same or a different shape, present in cluster, or in any predetermined orientation. For example, the periodic microstructures can comprise triangular, circular, semi-circular, elliptical, semi-elliptical, square, rectangular, hexagonal, trapezoidal, pentagonal, heptagonal, octagonal, nonagonal, decagonal, any other polygonal shape, star shape, or any random or irregular shape, or any combination thereof. In still further aspects, the periodic microstructures can comprise a variety of polyhedral shapes, parallelepipeds, prismatoids, prismoids, and the like, and combination thereof. In some additional exemplary aspects, the periodic microstructures can be polyhedral, conical, frusto-conical, pyramidal, frusto-pyramidal, spherical, partially spherical, hemispherical, ellipsoidal, dome-shaped, cylindrical, and any combination thereof. In some exemplary aspects, the periodic microstructures can have symmetric or asymmetric shape. In certain exemplary aspects, the periodic microstructures can exhibit a reflection symmetry or a mirror symmetry, a rotational symmetry, a translation symmetry, a helical symmetry, or any combination thereof. It is understood that the same sample can have a plurality of distinct shapes and/or symmetries, or it can include a number of replications of a single shape and/or symmetry. It is further understood that the location of the periodic microstructures having different shapes and symmetry can be determined by one of ordinary skill in the art depending on the desired results. In some exemplary aspects, the periodic microstructures comprising a variety of shapes and symmetries can be located on a substrate, in a specific pattern, in clusters wherein a number of the periodic microstructures having the same shape and/or symmetry are surrounded by the periodic microstructures having a different shape and/or symmetry. It is further understood that the periodic microstructures can comprise shapes having angle vertices of less than about 90°, about 90°, or more than about 90°, or a combination thereof. In yet other aspects, the periodic microstructures can have rounded vertices. In still other aspects, the periodic microstructures can have curved vertices.

In some aspects, the periodic microstructures comprise continuous parallel bars forming a grating-like structure. In yet other aspects, the periodic microstructures comprise continuous crossed bars forming a grating-like structure. In still further aspects, the periodic microstructure can comprise a combination of continuous parallel bars and continuous crossed bars. In yet further aspects, the periodic microstructures can have a shape of dots, discontinuous bars, or any combination thereof.

In some aspects, the plurality of spatially patterned periodic surface microstructures forms a grating-like structure. In yet other aspects, the plurality of spatially patterned periodic surface microstructures comprises dot shaped microstructures. In certain aspects, the plurality of spatially patterned periodic surface microstructures comprising dot shaped microstructures is grating-like.

In still further aspects, the dot shaped microstructures comprise a circular, square, or hexagonal array of microstructures.

It is understood that the microstructures described herein comprise nanostructures, microstructures, or any combination thereof. In some aspects, the microstructures can have any size that will allow achieving desirable results. In some aspects, the microstructures have a size from about 0.1 nm to about 100 μm, including exemplary values of about 0.5 nm, about 1 nm, about 5 nm, about 10 nm, about 50 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 1 μm, about 5 μm, about 10 μm, about 50 μm, and about 100 μm. In yet other aspects, the microstructures can have size of any value between two foregoing values.

In yet other aspects, the A is from about 100 nm to about 700 nm, including exemplary values of about 110 nm, about 125 nm, about 140 nm, about 155, about 170 nm, about 185, about 200 nm, about 215 nm, about 230, about 245 nm, about 260 nm, about 285 nm, about 300 nm, about 315 nm, about 330 nm, about 345 nm, about 360 nm, about 385 nm, about 400 nm, about 415 nm, about 430 nm, about 445 nm, about 460 nm, about 485 nm, about 500 nm, about 515 nm, about 530 nm, about 545 nm, about 560 nm, about 585 nm, about 600 nm, about 615 nm, about 630 nm, about 645 nm, about 660 nm, and about 685 nm.

In some aspects, the plurality of spatially patterned periodic surface microstructures can form any of disclosed herein structures having an amplitude, wherein the amplitude defines a height of each of the plurality of spatially patterned periodic surface microstructures. As disclosed herein, the film can be deposited on the polymeric substrate. In some aspects, any of disclosed herein microstructures have an amplitude from about 0.05 times of a thickness of the film to about 10 times of a thickness of the film, including exemplary values of about 1 time, about 1.5 time, about 2 times, about 2.5 times, about 3 times, about 3.5 times, about 4 times, about 4.5 times, about 5 times, about 5.5 times, about 6 times, about 6.5 times, about 7 times, about 7.5 times, about 8 times, about 8.5 times, about 9 times, and about 9.5 times of a thickness of the film.

In yet other aspects, the amplitude can be from about 0.1 nm to about 100 μm, including exemplary values of about 0.5 nm, about 1 nm, about 5 nm, about 10 nm, about 50 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 1 μm, about 5 μm, about 10 μm, about 50 μm, and about 100 μm. In yet other aspects, the amplitude can have any values between any two foregoing values. For example, in some aspects, the amplitude is from about 0.5 nm to about 1 μm, or from about 1 nm to about 500 nm, or from about 10 nm to about 1 μm.

In yet other aspects, the plurality of spatially patterned periodic surface microstructures can form a structure having an amplitude, wherein the amplitude defines a height of each of the plurality of spatially patterned periodic surface microstructures. As disclosed herein, the film can be deposited on the polymeric substrate. In some aspects, any of microstructures disclosed herein have an amplitude from about 0.05 times of a to about 10 times of a period A value, including exemplary values of about 0.5 time, about 1 time, about 1.5 times, about 2 times, about 2.5 times, about 3 times, about 3.5 times, about 4 times, about 4.5 times, about 5 times, about 5.5 times, about 6 times, about 6. 5 times, about 7 times, about 7.5 times, about 8 times, about 8.5 times, about 9 times, and about 9.5 times of a period A value. In still further aspects, microstructures disclosed herein can have an amplitude from about 0.5 times of a period A value to about 3 times of a period A value.

In still further aspects, the plurality of spatially patterned periodic surface microstructures can form a grating-like structure having the period A from about 100 nm to about 700 nm, and the amplitude from about 0.05 times of a thickness of the film to about 10 times of a thickness of the film deposited on the plurality of spatially patterned periodic surface microstructures. In still further aspects, the plurality of spatially patterned periodic surface microstructures can form a grating-like structure having the period A from about 100 nm to about 700 nm, and the amplitude from about 0.1 nm to about 100 μm. In these aspects, the period A and the amplitude can have any value between two foregoing values as disclosed herein.

In still further aspects, the plurality of spatially patterned periodic surface microstructures can form any of disclosed herein structures having the period A from about 100 nm to about 700 nm, and the amplitude from about 0.05 times of a thickness of the film to about 10 times of a thickness of the film deposited on the plurality of spatially patterned periodic surface microstructures. In these aspects, the period A and the amplitude can have any value between two foregoing values as disclosed herein.

In still further aspects, the plurality of spatially patterned periodic surface microstructures having any of the disclosed herein forms has the period A from about 100 nm to about 700 nm, and the amplitude from about 0.1 nm to about 100 μm. In these aspects, the period A and the amplitude can have any value between two foregoing values as disclosed herein.

In still further aspects, the articles disclosed herein have a ratio between a thickness of the film a period A from about 10:1 to about 1:10, including exemplary values of about 2:1 or 1:2, about 3:1 or 1:3, about 4:1 to about 1:4, about 5:1 to about 1:5, about 6:1 to about 1:6, about 7:1 to about 1:7, about 8:1 to about 1:8, and about 9:1 to about 1:9. In certain aspects, in addition to enabling bendable or rollable electronic devices, the inventive articles comprising flexible transparent conductive films (TCFs) can be also useful in functional design applications. In some exemplary aspects, use of inventive articles in mold electronics (IME), or structural electronics can obviate the need for placing printed circuit boards behind human machine interfaces. In such aspects, the necessary functionalities, such as transparent conductivity, graphics, or light management, are deposited on a flat two-dimensional surface, which is then formed into a three-dimensional object. Typical end uses of this process entail enabling both conductivity and design freedom over contoured surfaces found in automotive interiors, head ware, home or industrial appliances, or retail and residential window surfaces. Given that a mechanical strain or elongation is imposed during the 3D forming process, TCFs prepared from deposition of transparent conductive oxides on non-structured plastic substrates are prone to cracking and failure during this step. To date, TCFs amenable to this process are based on inherently flexible carbon nanotubes, metal mesh, or poly(3,4-ethylenedioxythiophene (PEDOT) coated plastic films. The inventive articles described herein, however, present a more economical and tunable alternative to these incumbent materials.

### C. FILMS

In some aspects, the article disclosed herein comprises a film deposited on the substrate. In some aspects, the film is a transparent conductive film. In certain aspects, the transparent conductive film comprises a transparent conductive oxide film.

In yet other aspects, the film comprises a transparent conductive oxide, conductive polymers, metal grids, carbon nanotubes, graphene, nanowire, ultra-thin metal films, silver nanoparticles, or any combination thereof In certain aspects, conductive polymers can comprise derivatives of polyacetylene, polyaniline, polypyrrole, or polythiophenes. In yet other aspects, the conductive polymers can comprise poly(3,4-ethylenedioxythiophene) (PEDOT), polystyrene sulfonate (PSS), poly(4,4-dioctylcyclopentadithiophene), or any combination thereof. In yet other aspects, the film does not comprise conductive polymers, metal grids, carbon nanotubes, graphene, nanowire, ultra-thin metal films, silver nanoparticles, or any combination thereof. In some aspects, it is also contemplated that any of the foregoing materials can be excluded.

In still further aspects, the film comprises transparent conductive oxides. In certain aspects, the transparent conductive oxides can be doped. In yet further aspects, the doping can comprise n- or p-doping. It is understood that materials and elements used to form n- or p-doping will depend on a specific type of a transparent conductive film. In some exemplary and non-limiting aspects, transparent conductive films comprising zinc oxides can be n-doped, for example and without limitation, with metals such as aluminum, copper, silver, gallium, magnesium, cadmium, indium, tin, scandium, yttrium, cobalt, manganese, chrome, or boron, or any combination thereof. In yet other aspects, transparent conductive films comprising zinc oxides can be p-doped with nitrogen, phosphorous, or any combination thereof.

In certain aspects, the transparent conductive oxides comprise lithium doped nickel oxide, sodium and/or aluminum doped zinc oxide, magnesium and/or nitrogen doped chromium oxide, indium tin oxide, fluorine doped tin oxide, magnesium doped delafossite (CuCrO₂), indium doped magnesium zinc oxide (Mg₁₋ₓZnₓO), aluminum doped magnesium zinc oxide (Mg₁₋ₓZnₓO), mayenite (Mg₁₂Al₁₄O₃₃), amorphous indium zinc oxide, or any combination thereof. In yet other aspects, the film comprises indium tin oxide.

In certain aspects, the film deposited on the substrate has a thickness from about 30 nm to about 10 μm, including exemplary values of about 50 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 950 nm, about 1 μm, about 2 μm, about 3 μm, about 4 μm, about 5 μm, about 6 μm, about 7 μm, about 8 μm, and about 9 μm. In yet other aspects, the film thickness can have any value between any two foregoing values. For example, the film thickness can be between about 50 nm and about 1 μm, about 100 nm and about 5 μm, or from about 500 nm to about 10 μm.

In still further aspects, the deposited film is continuous over the whole surface of the substrate. In yet other aspects, the deposited film is substantially continuous over the whole surface of the substrate.

In some aspects, the deposited film is substantially smooth. In yet other aspects, the deposited film is smooth.

In certain aspects, it is understood that the deposited film has at least one point of contact with at least one of the plurality of spatially patterned periodic surface microstructures present on the substrate. In still further aspects, it is understood that the film is deposited on the plurality of spatially patterned periodic surface microstructures present on the substrate.

In certain aspects, the film disclosed herein has a transmission equal to or greater than about 90%, equal to or greater than about 91%, equal to or greater than about 92%, equal to or greater than about 93%, equal to or greater than about 94%, equal to or greater than about 95%, equal to or greater than about 96%, equal to or greater than about 97%, equal to or greater than about 98%, or equal to or greater than about 99% in a wavelength range from about 350 nm to about 800 nm. It is further understood that in certain aspects, the film disclosed herein has a transmission substantially equal to about 100% in a wavelength range from about 350 nm to about 800 nm. It is further understood that wavelengths described herein include wavelengths of about 380 nm, about 400 nm, about 420 nm, about 450 nm, about 480 nm, about 500 nm, about 520 nm, about 550 nm, about 580 nm, about 600 nm, about 620 nm, about 650 nm, about 680 nm, about 700 nm, about 720 nm, about 750 nm, and about 780 nm.

In still further aspects, the film disclosed herein exhibits a refractive index from about 1.3 to about 2.0, including exemplary values of about 1.4, about 1.5, about 1.6, about 1.7, about 1.8, and about 1.9.

In some aspects, disclosed herein is an article comprising: a polymeric substrate comprising a plurality of spatially patterned periodic surface microstructures, wherein the plurality of spatially patterned periodic surface microstructures forms a grating-like structure; an indium tin oxide film deposited on the polymeric substrate, wherein the film has at least one point of contact with at least one of a plurality of spatially patterned periodic surface microstructures, wherein the patterned periodic surface microstructures have a period A from about 100 nm to about 700 nm and amplitude from about to 0.05 times of a thickness of the film to about 10 times of a thickness of the film, and wherein the article is bendable in at least one direction to a bending diameter of about 3.5 mm or less and wherein no substantial structural failure of the article is observed. In these aspects, the period A and the amplitude can have any value between two foregoing values as disclosed herein.

In other aspects, disclosed herein is an article comprising: a polymeric substrate comprising a plurality of spatially patterned periodic surface microstructures, wherein the plurality of spatially patterned periodic surface microstructures forms a grating-like structure; an indium tin oxide film deposited on the polymeric substrate, wherein the film has at least one point of contact with at least one of a plurality of spatially patterned periodic surface microstructures, wherein the patterned periodic surface microstructures have a period A from about 100 nm to about 700 nm and amplitude from about to 0.05 times of a thickness of the film to about 10 times of a thickness of the film, and wherein the article is bendable in at least one direction to a bending diameter of about 3.8 mm or less and wherein no substantial structural failure of the article is observed. In these aspects, the period A and the amplitude can have any value between two foregoing values as disclosed herein.

In still further aspects, disclosed herein is an article comprising: a polymeric substrate comprising a plurality of spatially patterned periodic surface microstructures, wherein the plurality of spatially patterned periodic surface microstructures forms a dot shaped microstructures comprising a circular, a square, a hexagonal array microstructures, or a combination thereof; an indium tin oxide film deposited on the polymeric substrate, wherein the film has at least one point of contact with at least one of a plurality of spatially patterned periodic surface microstructures, wherein the patterned periodic surface microstructures have a period A from about 100 nm to about 700 nm and amplitude from about to 0.05 times of a thickness of the film to about 10 times of a thickness of the film, and wherein the article is bendable in at least one direction to a bending diameter of about 3.8 mm or less and wherein no substantial structural failure of the article is observed. In these aspects, the period A and the amplitude can have any value between two foregoing values as disclosed herein,

### D. METHODS

Disclosed herein are methods of making disclosed articles. In some aspects, the method comprises depositing a film on a substrate. In certain aspects, the method comprises depositing a film on a patterned substrate. In certain aspects, it is further understood that any films disclosed herein can be deposited on any substrates disclosed herein. In some aspects, the depositing can be done by any methods known in the art. In certain aspects, the depositing can comprise spray pyrolysis, sol gel technology, solution deposition, atomic layer deposition (ALD), vapor phase deposition, chemical vapor deposition (CVD), low pressure (LP), metal organic (MO), plasma enhanced (PE) chemical vapor deposition (CVD), vacuum deposition, electron beam evaporation, ion assisted plasma evaporation, direct current (DC) deposition, pulsed DC (PDC) deposition, magnetron DC sputtering, high power pulsed magnetron sputtering (HPPMS), radio frequency (RF) magnetron sputtering, thermal evaporation, thermal plasmas, pulsed laser deposition (PLD), low temperature hydro/solvo-thermal process, or any combinations thereof. In still further aspects, it is understood that the deposited film can undergo post-processing steps. In some aspects, the post processing steps comprise thermal annealing, oxygen-plasma treatments, acid/base treatments, or any combination thereof. In still further aspects, the thermal annealing can be performed in any atmosphere, for example, and without any limitation, in nitrogen, oxygen, air, or argon.

In certain aspects, the substrate disclosed herein is patterned. In some aspects, a desired pattern is first designed to provide desirable characteristics to the disclosed article. In certain aspects, the desired pattern is transferred on a substrate using a mask. In still further aspects, the desired pattern is transferred on a substrate by means of photolithography, hard masking process, ink printing, nanoimprint method, embossing method, electron or ion beam writing, or any combination thereof. In yet other aspects, the desired pattern can be transferred on a substrate using a photoresist.

It is understood that the patterning can be performed by any methods known in the art. It is understood that a specific method of forming patterns on a substrate can depend on a type of a substrate. It is further understood that a specific method of forming patterns on a substrate can also depends on a precision and accuracy of the desired patterned to be formed. In certain aspects, the pattern can be formed by a method comprising a chemical etching, a solution based etching, a plasma etching, a molding, or any combination thereof. In still further aspects, the patterned substrate can be formed by expositing the substrate to plasma. In other aspects, the patterned substrate can be formed by molding. In still further aspects, the patterned substrate can be formed by a chemical etching. In still further aspects, the patterned substrate can be formed by nano-imprinting or a direct embossing. In still further aspects, the patterned substrate can be formed by any combination of the methods mentioned above.

In certain aspects, the solution based etching comprises exposure of the substrate with a desired pattern to one or more aqueous solution, organic solvents, organic acids and/or base, inorganic acids and/or base. It is understood that one of ordinary skill in the art can choose the specific solution based on a specific chemistry of the substrate. In some aspects, the solution comprises hydrofluoric acid, acetone, trichloroethylene, isopropyl alcohol, methanol, ethanol, tetrahydrofuran, n-methyl-2-pyrrolidone, or dimethylformamide, or any combination thereof.

In yet other aspects, the plasma etching comprising exposure of the substrate to a plasma environment. It is further understood that one of ordinary skill in the art can choose specific plasma conditions, e.g. a type of plasma etch, a reactant gas, plasma power, etc., based on a specific chemistry of the substrate. In some aspects, plasma etch comprises using a reactive ion etching (RIE), a microwave plasma, inductively coupled plasma (ICP), electron cyclotron plasma (ECR), or any combination thereof. In some aspects, plasma etch can comprise use of an etchant gas. In certain aspects, the etchant gas can comprise oxygen, hydrogen, fluorocarbons, halogens, argon, or any combination thereof.

In some aspects, the desired pattern can comprise any form or shape. In yet other aspects, the periodic microstructures can comprise features of any shape or symmetry. In still further aspects, the periodic microstructures present on the substrate can have the same or a different shape, present in cluster, or in any predetermined orientation. For example, the periodic microstructures can comprise triangular, circular, semi-circular, elliptical, semi-elliptical, square, rectangular, hexagonal, trapezoidal, pentagonal, heptagonal, octagonal, nonagonal, decagonal, any other polygonal shape, star shape, or any random or irregular shape, or any combination thereof. In still further aspects, the periodic microstructures can comprise a variety of polyhedral shapes, parallelepipeds, prismatoids, prismoids, and the like, and combination thereof. In some additional exemplary aspects, the periodic microstructures can be polyhedral, conical, frusto-conical, pyramidal, frusto-pyramidal, spherical, partially spherical, hemispherical, ellipsoidal, dome-shaped, cylindrical, and any combination thereof. In some exemplary aspects, the periodic microstructures can have symmetric or asymmetric shape. In certain exemplary aspects, the periodic microstructures can exhibit a reflection symmetry or a mirror symmetry, a rotational symmetry, a translation symmetry, a helical symmetry, or any combination thereof. It is understood that the same sample can have a plurality of distinct shapes and/or symmetries, or it can include a number of replications of a single shape and/or symmetry. It is further understood that the location of the periodic microstructures having different shapes and symmetry can be determined by one of ordinary skill in the art depending on the desired results. In some exemplary aspects, the periodic microstructures comprising a variety of shapes and symmetries can be located on a substrate, in a specific pattern, in clusters wherein a number of the periodic microstructures having the same shape and/or symmetry are surrounded by the periodic microstructures having a different shape and/or symmetry. It is further understood that the periodic microstructures can comprise shapes having angle vertices of less than about 90°, about 90°, or more than about 90°, or a combination thereof. In yet other aspects, the periodic microstructures can have rounded vertices. In still other aspects, the periodic microstructures can have curved vertices.

As disclosed herein, in certain aspects, the desired pattern comprises a plurality of spatially patterned periodic surface microstructures of the disclosed size. In certain aspects, for example, a plurality of spatially patterned periodic surface microstructures comprises parallel or crossed bars. In yet other aspects, a plurality of spatially patterned periodic surface microstructures can have a sinusoidal form. In some aspects, the plurality of spatially patterned periodic surface microstructures forms a grating-like structure. In yet other aspects, the plurality of spatially patterned periodic surface microstructures comprises dot shaped microstructures. In still further aspects, the dot shaped microstructures comprise a circular, square, or hexagonal array of microstructures.

It is understood that the etching time and specific etching conditions will depend on desirable dimensions of each of the plurality of spatially patterned periodic surface microstructures. It is further understood that each of the plurality of spatially patterned periodic surface microstructures can have various walls or facets. In some aspects, the walls of each of the plurality of spatially patterned periodic surface microstructures present on the substrate surface can form substantially an about 90° angle with the substrate. In yet other aspects, the walls of each of the plurality of spatially patterned periodic surface microstructures present on the substrate surface can form substantially less than an about 90° angle, less than less than an about 89° angle, less than an about 88° angle, less than an about 87° angle, less than an about 86° angle, less than an about 85° angle, less than an about 84° angle, less than an about 83° angle, less than an about 82° angle, less than an about 81° angle, or less than an about 80° angle with the substrate. In still further aspects, the walls of each of the plurality of spatially patterned periodic surface microstructures present on the substrate surface can form substantially greater than an about 90° angle, greater than an about 91° angle, greater than an about 92° angle, greater than an about 93° angle, greater than an about 94° angle, greater than an about 95° angle, greater than an about 96°, angle greater than an about 97° angle, greater than an about 98° angle, greater than an about 99° angle, or greater than an about 100° angle with the substrate.

In certain aspects, the deposited film has at least one point of contact with at least one of the plurality of spatially patterned periodic surface microstructures. In yet a further aspect, the deposited film substantially conforms to morphology of the patterned substrate.

It is further understood that the methods described herein can be utilized to form articles on a commercial scale. In some aspects, a plurality of the spatially patterned periodic surface microstructures can be formed on a substrate having any desirable area. In still further aspects, the film disclosed herein can be deposited on the patterned substrate having any desirable area. For example, and without limitation, the film disclosed herein can be deposited on the patterned substrate having an area of about 1 in², about 10 in², about 100 in², about 1,000 in², about 10 ft², or about 100 ft².

In still further aspects, disclosed herein a method comprising: forming a patterned polymeric substrate comprising a plurality of spatially patterned periodic surface microstructures; and depositing an indium tin oxide film on the substrate; wherein the plurality of spatially patterned periodic surface microstructures forms a grating-like structure having a period A from about 100 nm to about 700 nm and amplitude from about to 0.05 times of a thickness of the film to about 10 times of a thickness of the film; wherein the film has at least one point of contact with at least one of a plurality of spatially patterned periodic microstructures; and wherein the article is bendable in at least one direction to a bending diameter of about 3.5 mm or less and wherein no substantial structural failure of the article is observed. In these aspects, the period A and the amplitude can have any value between two foregoing values as disclosed herein.

In still further aspects, the plurality of spatially patterned periodic surface microstructures can form any of disclosed herein structures having the period A from about 100 nm to about 700 nm, and the amplitude from about 0.05 times of a thickness of the film to about 10 times of a thickness of the film deposited on the plurality of spatially patterned periodic surface microstructures. In still further aspects, the plurality of spatially patterned periodic surface microstructures can form any of disclosed herein structures having the period A from about 100 nm to about 700 nm, and the amplitude from about 0.1 nm to about 100 μm. In these aspects, the period A and the amplitude can have any value between two foregoing values as disclosed herein.

### E. EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the invention and are not intended to limit the scope of what the inventors regard as their invention. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### 1. Example 1

1×1 inch (25.4×25.4 mm²) PET films with a thickness of 125 μm were used as the substrates. PET sheets were purchased from TAP Plastics Inc. MCC Primer, S1811 positive photoresist, Thinner-P and MF 319 developer were purchased from Microchem. Laser interference photolithography was employed to create a submicron grating structure composed of a positive photoresist S1811, and which then became a template for the ITO deposition. In order to produce the structure with a specific height, for example 180 nm, the dilute photoresist solution was used, in which the ratio of pure photoresist to Thinner-P was 1:1 in volume. The photoresist solution was spin-coated at 7,000 rpm for 40 s onto a PET substrate and followed by prebaking on hot plate at 120° C. for 60 s. The photoresist coated film was then mounted in the interference lithography set-up and exposed to the UV laser with 405 nm wavelength for 4 min. After exposure, the substrate was dipped into MF 319 developer for 7 s right away, followed by washing step with deionized water, in which the substrate was rinsed for 7 s twice. After that, the substrate was dried with N₂ flow. ITO was then deposited on the periodic grating pattern template comprising with photoresist on PET by roll-to-roll sputtering deposition at room temperature.

The cross-sectional images of ITO periodic submicron grating structure were obtained using a scanning electron microscopy (SEM, Hitachi S-4700). The specimens were cross-sectioned in liquid nitrogen in order to minimize the tearing damage to the polymer substrate during the cutting process. The transmittance of ITO nanopatterned PET substrates was measured with an integrating sphere and spectrometer/CCD camera (Acton 300, PIXIS, Princeton Instruments).

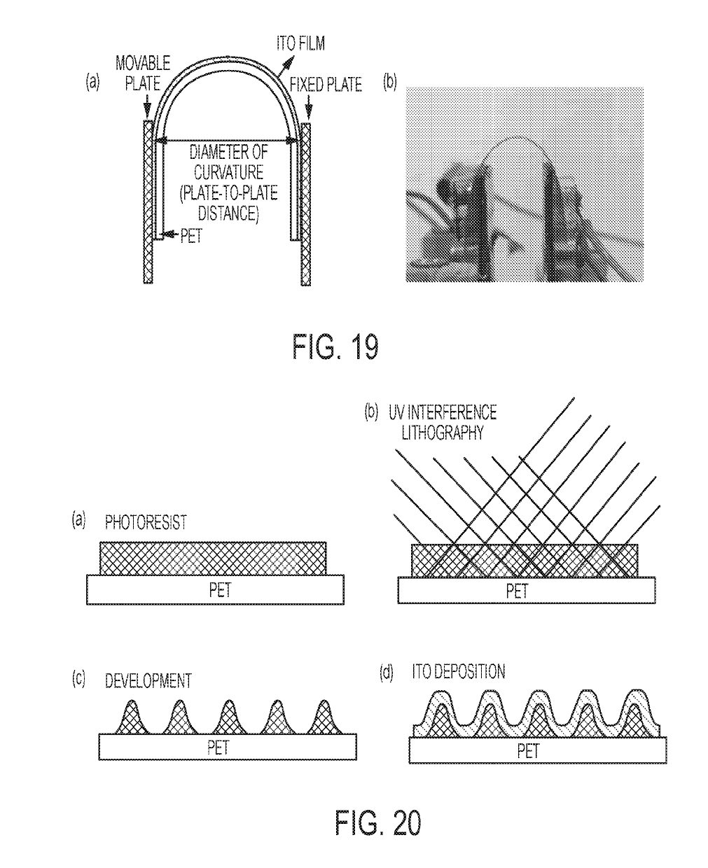

The initial sheet resistance of ITO periodic submicron grating structure was determined by the mean value of at least three different measurements with the same condition by using a four-point probe system (Signatone 1160 series probe station). The mechanical flexibility of ITO nanopatterned PET substrates was then measured with a lab-made bending system comprised of two parallel plates with a programmable separation distance as shown in FIG. 19. During the forward and backward bending process, the electrical sheet resistance of the specimen was measured by four-point measurement via NI-4065 multimeter as a function of bending diameter of curvature, which was the distance between the two plates of the bending system (FIG. 19(a)). Simultaneously, the compressive strain was calculated according to the real-time bending diameter. The test specimens were subjected to multiple bending cycles (50 cycles) with the minimum bending diameter of curvature being 3.2 mm limited by the apparatus.

The sample fabrication process is summarized in two simple steps (FIG. 20): (1) fabrication of the submicron grating structure with photoresist; and (2) deposition of ITO onto the photoresist template. Since the spring-like structure is preferably transparent in the whole visible range, the features are fabricated with sub-optical wavelength dimensions to avoid angular diffractive effects. In some aspects, the mask-less laser interference lithography (LIL) can be used. Adequate periodicity and the height of the spring-like structure was chosen by diffractive optics modeling and fabricated by precisely control the exposure dose and angle between the two interference beams as known in the art.

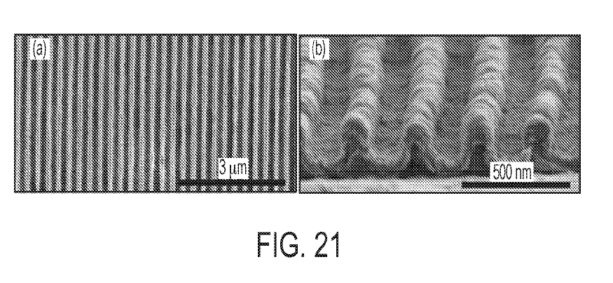

FIG. 21 shows the surface and cross-sectional micrographs of the ITO periodic submicron grating structure deposited on the PET substrates. The ITO grating has a 285-nm periodicity and a total height of 230 nm (which includes the grating height of photoresist and the thickness of ITO layer). In this exemplary aspect, the deposition of ITO on the grating template was substantially uniform. Compared to control non-patterned samples deposited at the same time (not shown), the peaks and valleys of the grating were coated with the same thickness of the control flat ITO layer and only the walls of the grating show a slightly thinner oxide layer. The measured sheet resistances of all ITO films on patterned PET substrates fabricated via the same conditions were approximately the same, with a deviation of 5%. The lowest sheet resistance observed was 209 Ωsq⁻¹, which corresponded to a resistivity of 1.4×10⁻³ Ωcm (this was calculated using the thickness of the ITO layer). Compared to resistivity values previously reported for porous ITO films via solution-based process (the data reported by Heusing, S.; de Oliveira, P. W.; Kraker, E.; Haase, A.; Palfinger, C.; Veith, M. Wet Chemical Deposited ITO Coatings on Flexible Substrates for Organic Photodiodes. Thin Solid Films 2009, 518 (4), 1164-1169 and Maksimenko, I.; Wellmann, P. Low Temperature Processing of Hybrid Nanoparticulate Indium Tin Oxide (ITO) Polymer Layers and Application in Large Scale Lighting Devices. Thin Solid Films 2011, 519 (17), 5744-5747) and ITO nanoarray via sputtering-based process (reported by Yun, J.; Park, Y. H.; Bae, T. S.; Lee, S.; Lee, G. H. Fabrication of a Completely Transparent and Highly Flexible Ito Nanoparticle Electrode at Room Temperature. ACS Appl. Mater. Interfaces 2013, 5 (1), 164-172), the sheet resistance of the inventive ITO nanopatterned films was about 20% lower than those of the ITO nanoarray and the lowest value reported for porous ITO films. Relative to the control flat samples, the electrical sheet resistances of the patterned specimens were approximately 20% higher. Without being bound by theory, this difference is believed due to a longer conductive path of ITO patterned structure when compared to that of the flat sample.

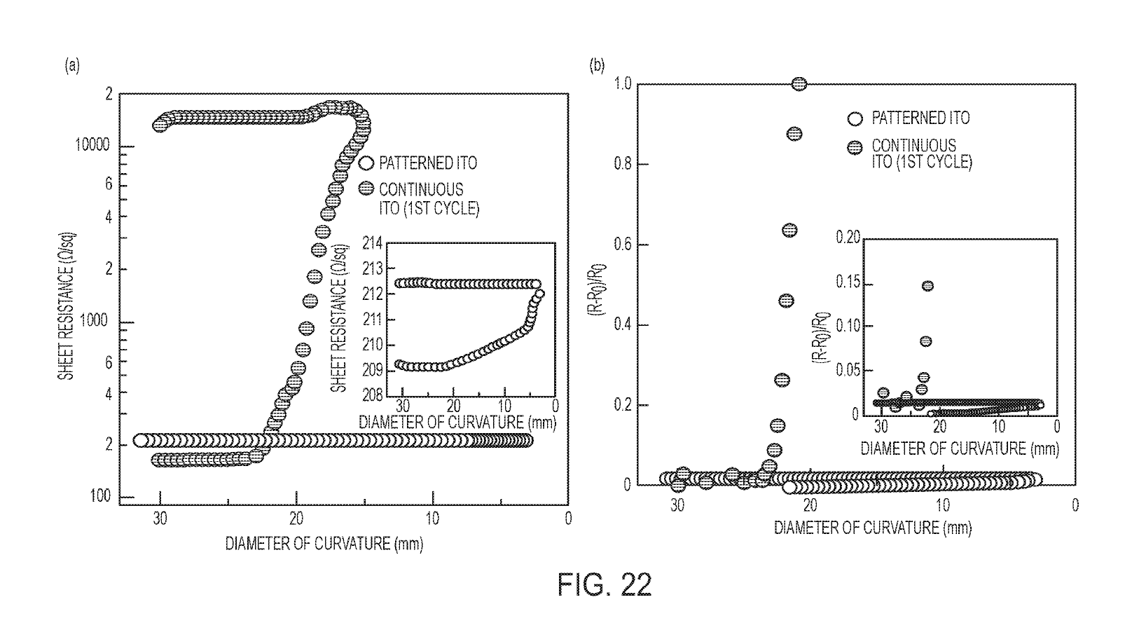

The mechanical flexibility and durability of the ITO periodic submicron grating structures were tested by applying a high tensile or compressive stress to the ITO nanopattern via bending as illustrated in FIG. 19. During the bending test, the sheet resistance was measured when the ITO coated PET substrate was subjected to a particular diameter of curvature in a complete cycle (which included the compressive and decompressive process). The electrical failure in this study was determined by the relative resistance increase, which was calculated by using the following expression, (R−R₀)/R₀, where R₀ is the initial resistance and R is the resistance under compressive or tensile stress. FIG. 22a and FIG. 22b show the sheet resistance and the resistance change upon bending the first cycle for the flat control and the patterned ITO samples, respectively.

It was determined that for flat control samples, when the curvature diameter has decreased to barely 23.5 mm, the sheet resistance of flat ITO film has already undergone a very large increase, implying the appearance of cracks and film delamination. The cracks deteriorated the sheet resistance of the film, propagating the entire width of the sample, leading to an irreversible structural failure and consequent electrical failure. It was found that, in contrast, the ITO patterned sample stays approximately the same all the way to the smallest possible bending in the instrument. The relative resistance increase of the inventive ITO patterned film was less than 1.6%.

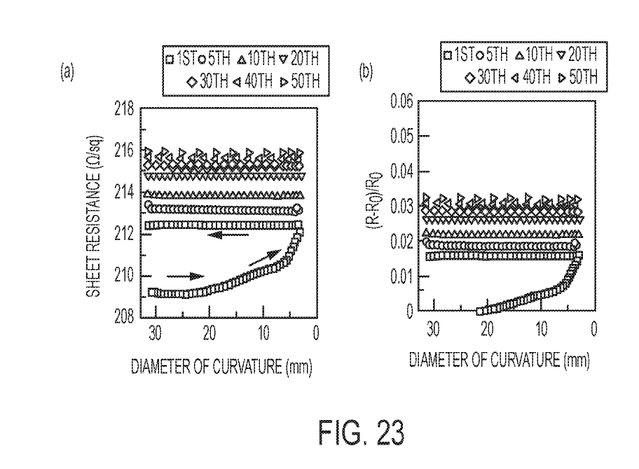

Interestingly, it was shown that with only 1.6% resistance deterioration, the first cycle is actually the biggest single damaging flexion the film suffers upon multiple consecutive bending tests. FIG. 23 shows the sheet resistance and relative resistance increase of the ITO film with the periodic submicron patterning over multiple bending cycles. The super flexibility and durability of this ITO patterned PET substrate is evident by reaching 3.2 mm diameter of curvature and surviving after cycling for more than 50 times without failure. Given the miniscule difference between 40 to 50 cycles, one can reasonably expect many hundreds of successful cycles afterwards.

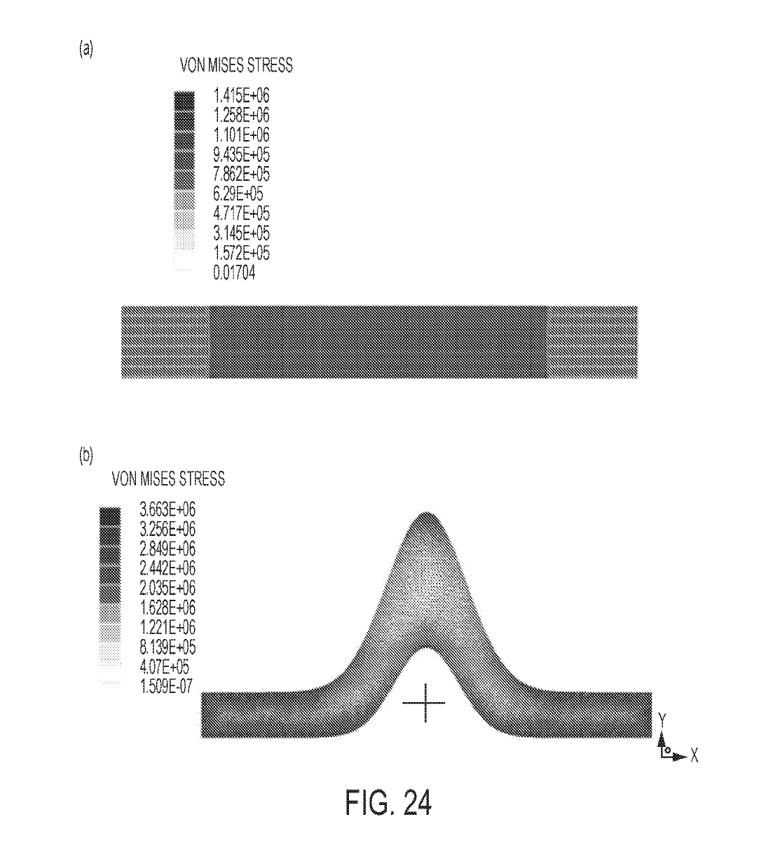

FIG. 24 presents the von Mises stress map for both ITO pattern and flat film undergoing the same strain. For reference, the critical stress for cracking ITO in tensile test are σ_{c}=5.8×10⁵ Pa and strain ε_{c}=0.005 (experimentally determined by standard tensile tests in conventional films). As it can be seen from the FIG. 24, the von Mises stress in the inventive ITO pattern is much lower than the critical stress of ITO at all points. It was shown that for continuous ITO film, the film is expected to crack at this point. It was hypothesized that during the bending process, the inventive ITO pattern can survive much smaller curves than flat counterpart. It was shown that the same simulation with strains produced under a 3 mm diameter curvature on a 125 μm PET still generates stress maps under σ_{c}, in full agreement with the experimental observations presented above.

It was demonstrated on the patterned sample stress map that the stress distribution is substantially non-uniform, with some high spot at the “knees” of the pattern. Without wishing to be bound by theory, a reason for these high spot at the “knees” of the pattern, is that, in tensile mode, the stretching is carried out by flexing the lowest point of the spring with a combination of local tensile and compressive stresses. The larger the aspect ratio of the spring structure, the smaller the flexing needed to accommodate the substrate strain. Therefore, the potential for cracking is expected to be low and those local stress points can be consider fully benign, as material does not displace but hinges around the lowest points.

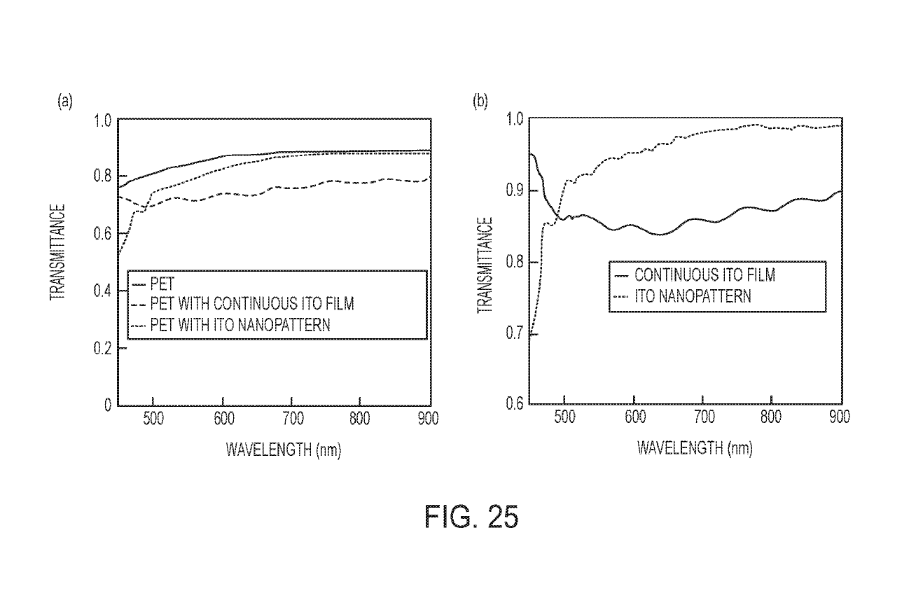

To achieve better antireflective (AR) characteristics in the application of optoelectronic devices, one of the solutions inspired from nature is the moth-eye antireflective scheme: the eyes and wings of certain species of moth are covered in arrays of tapered pillars with a nano-scale period and height. Herein, the fabrication of the inventive ITO grating pattern at the right length scale and with a suitable periodicity for the optical matching creates a bonus-added moth-eye anti-reflector. It was shown that compared to the conventional flat ITO film, the inventive ITO grating patterned films with 285 nm periodicity exhibited a higher transmittance in the majority of the visible and near infrared spectrum range (500˜900 nm) as shown in FIG. 25a.

The 125 μm thickness PET substrates used in this disclose, present on their own a ˜90% transmittance in the whole visible near IR range. When normalized to this PET transmittance (FIG. 25b), the transmittance of ITO nanopattern alone is above 90% in the visible range and reaches 98% at 700 nm wavelength. In contrast, the normalized transmittance for flat ITO film is below 90% in the whole visible range. In some aspects, the patterned samples can exhibit a transmittance decrease in the blue region (450˜500 nm). Without wishing to be bound by theory, in these aspects, while the photoresist present in the structure can contribute to some spurious blue light absorption, this blue deficiency can be also caused because the moth-eye effect does not reach those very short wavelengths. It is further understood that the AR characteristics can be very sensitive to the periodicity of the pattern if the features are not significantly smaller than the wavelength. In certain aspects, decrease in the grading period can result in decrease of the blue light adsorption. It was found, based on optical simulations, that when the periodicity of grating structure decreases to <235 nm and the structure height shrinks to 80 nm, the short wavelength problems shift to deeper UV region. Under those conditions, the specular transmittance can be kept above 90% in the whole visible wavelength region.

### 2. Example 2

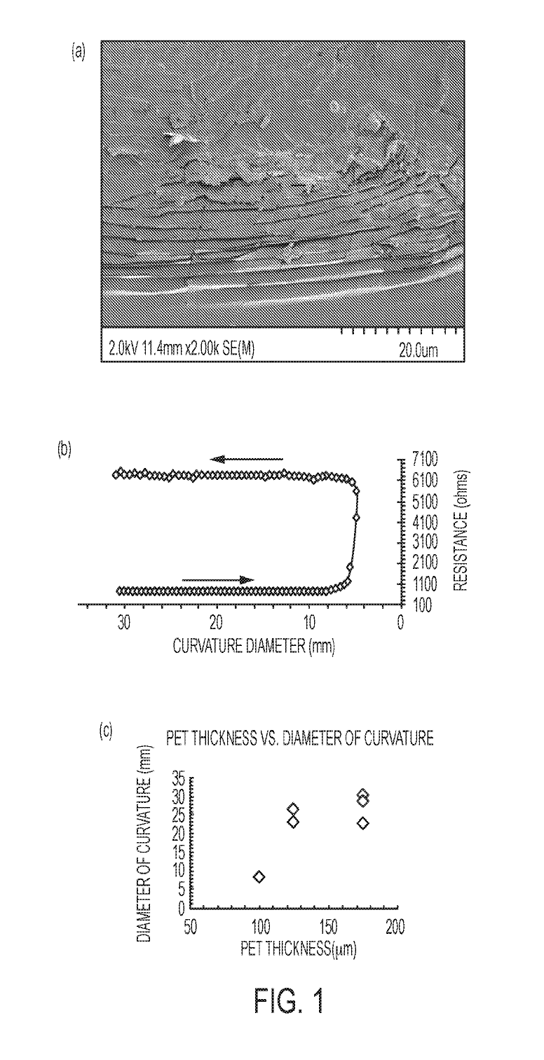

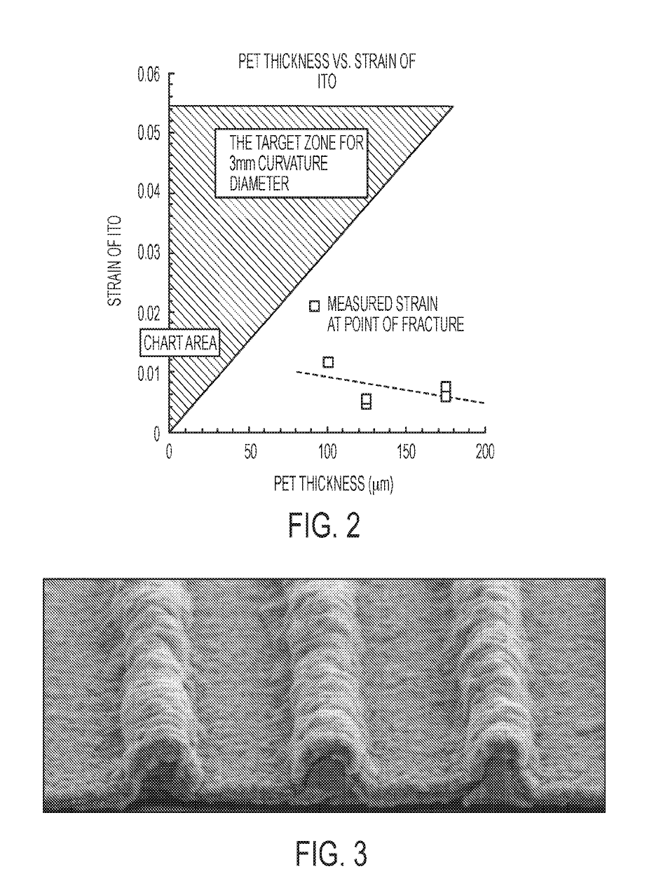

Indium tin oxide (ITO) film having 200 nm thicknesses has been deposited on a flat 125 μm PET sample to form a control article. The control article was bent to different ratios of curvature. The SEM image shown in FIG. 1(a) demonstrates cracks and ruptures of the film as a result of bending. FIG. 1(b) shows a significant change in a film resistance as a function of bending the article to different ratios of curvature. The large jump in resistance is correlated to a film cracking that does not recover after release of the article. FIG. 1(c) shows cracking points at different bending diameters as a function of the substrate thickness. It was demonstrated that with thicker substrates less bending is possible. The results demonstrated on FIG. 1(c) have been re-plotted to show the strain of the film at the film rupture (FIG. 2). The straight line in FIG. 2 describes the target zone for 3 mm diameter of bending curvature. When the strain of ITO lies on or beyond this line, the film would be safe enough to avoid suffering structural failure.

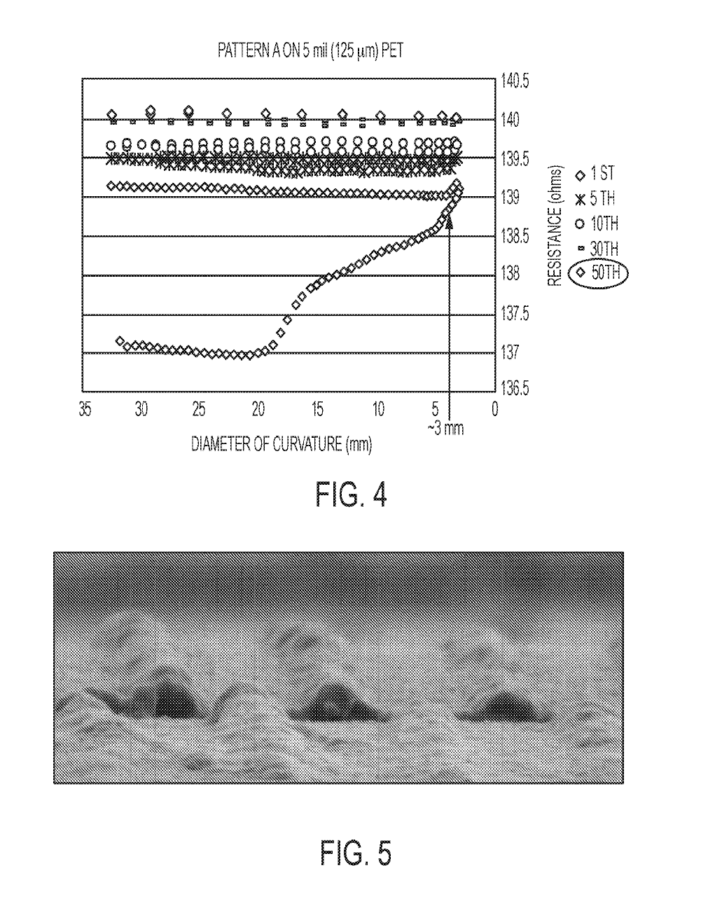

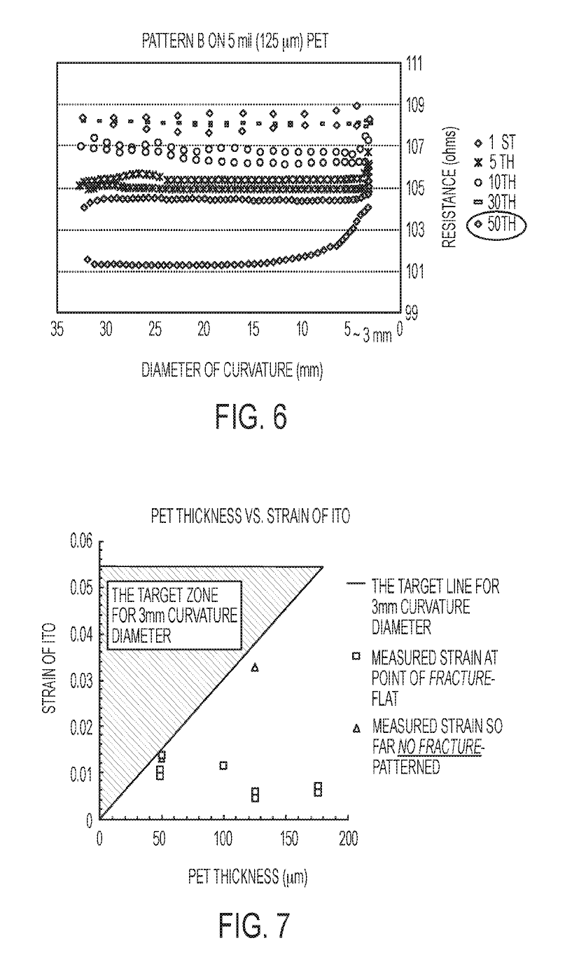

To form an inventive article, the substrate was patterned to form a plurality of spatially patterned periodic surface microstructures by known in the art techniques. The ITO film was deposited on the patterned substrate. FIG. 3 and FIG. 5 show SEM images of the film deposited on patterned microstructures having different shapes due to different exposure time of the laser lithography (pattern A and B). Both samples were subjected to bending testing and a resistivity of each film was measured as a function of the bending curvature (FIG. 4 and FIG. 6). It was demonstrated that both articles remained highly conductive over large range of bending curvatures, including bending to a curvature of 3 mm for at least 50 repetitive cycles of bending.

FIG. 7 shows that when compared to the flat PET films, the measured strain of ITO in the patterned PET films almost lies on the target zone of the ITO strain with 3 mm diameter of curvature. Therefore, the inventive sample does not fracture even at higher strains.

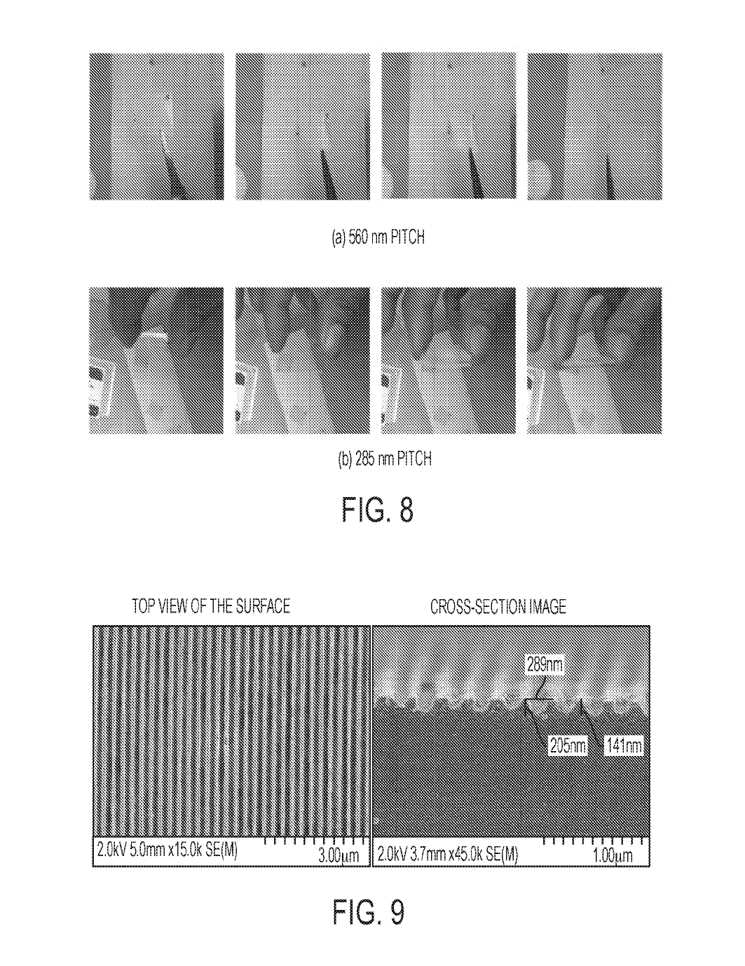

FIG. 8 depicts photographic images of exemplary articles comprising a substrate having a plurality of spatially patterned periodic microstructures with a period of (a) 560 nm and (b) 285 nm. In both FIGS. 8(a) and 8(b), from left to right, the sample was rotated with 0°, 30°, 60° and 90°, respectively. Comparing FIG. 8(a) with 8(b), the optical improvement by reducing the pitch of patterns is obvious. It is clear that from FIG. 8(a) when the sample was put horizontally, the one with 560 nm pitch looks reddish and rainbow-colored. And with the rotation angle increase, the color always changed and existed until when the sample was put vertically. However, the situation changed for the patterned sample with 285 nm pitch, which is shown in FIG. 8(b). When it was put horizontally, the sample looks transparent. Only when the angle of rotation becomes larger and larger, the situation would be getting worse.

FIG. 9 shows a SEM images (a) top view and (b) cross section for periodic surface microstructures having a period of 289 nm and an amplitude of 205 nm.

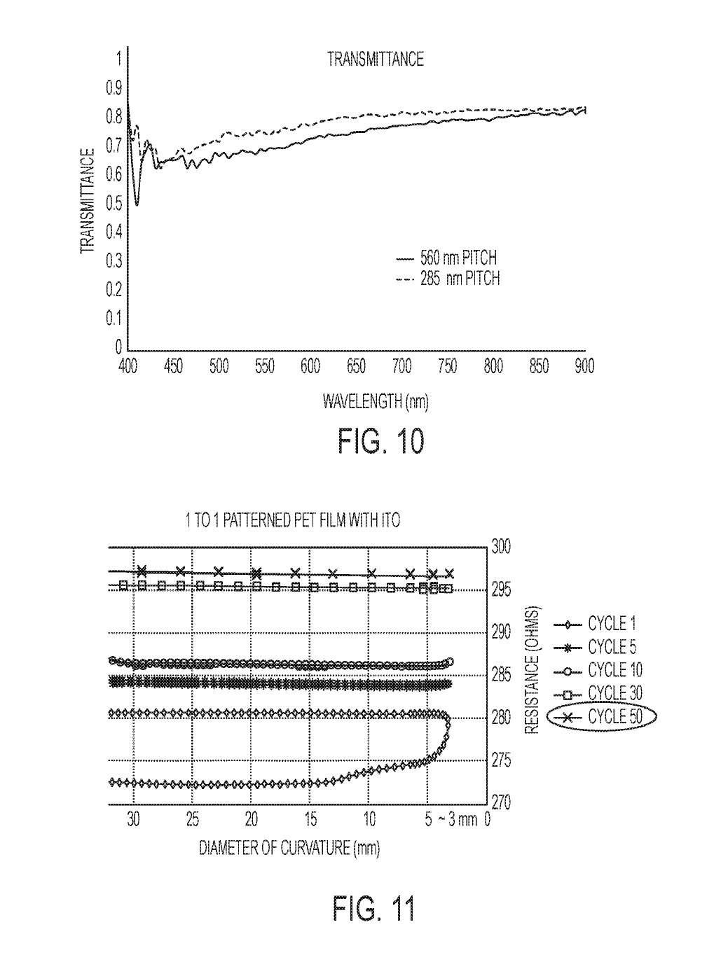

FIG. 10 shows transmittance of the article as a function of the surface microstructures period over a large number of wavelength (350 nm-950 nm).

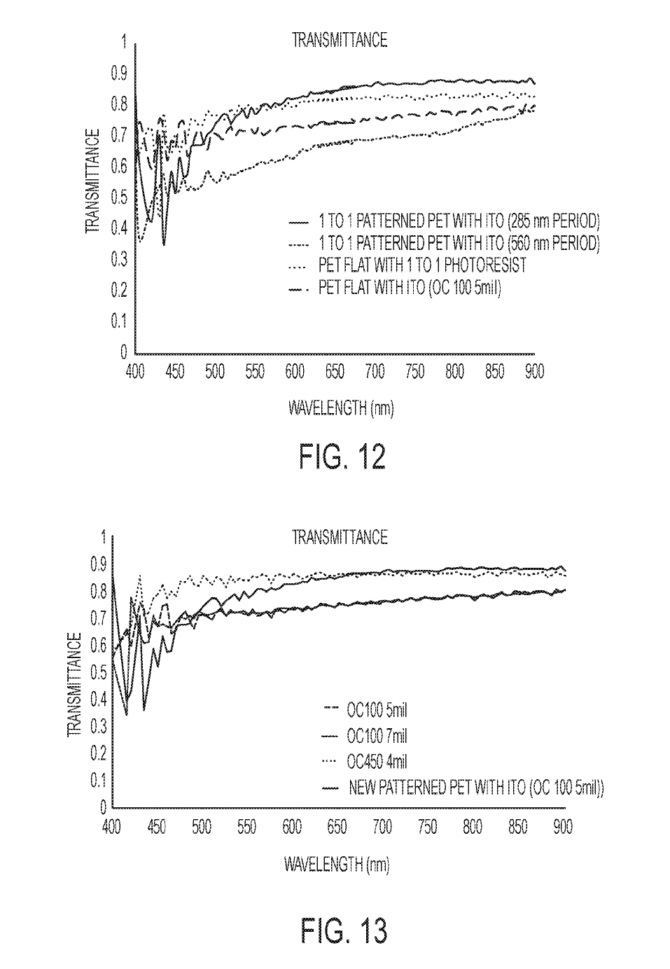

FIG. 11 shows the bending test results of the 1:1 patterned PET film with deposited ITO (with 285 nm period). In some plots, this film is depicted as a new 1:1 patterned PET film. It is further understood that the 1:1 patterned PET film refers to a patterned film formed on a photoresist, for example S1811 positive photoresist, diluted with the solvent in 1:1 ratio. It is further understood that this disclosed photoresist is an exemplary photoresist and any known in the art photoresists can be utilized. The samples were subjected to bending testing and a resistivity of each film was measured as a function of the plate-to-plate distance of the bending station (which is used to describe the bending curvature). It was demonstrated that the articles remained highly conductive over a large range of bending curvatures, including bending to a curvature of 3 mm for at least 50 repetitive cycles of bending. FIG. 12 and FIG. 13 show the transmittance of the 1:1 patterned PET film with deposited ITO (with 285 nm period). In FIG. 12, it is clear that compared to the 1:1 patterned PET film with ITO (with 560 nm period) (in some embodiments this patterned PET can be depicted as an old film), the flat PET film with 1:1 photoresist or flat PET film with the same thickness of ITO deposition, the 1:1 patterned film with 285 nm period shows much higher transmittance. Furthermore, compared with other Eastman commercial flat PET films with different thickness and also with different thickness of ITO deposition, the newest inventive patterned films still show obvious advantages in transmittance (FIG. 13).

### 3. Example 3

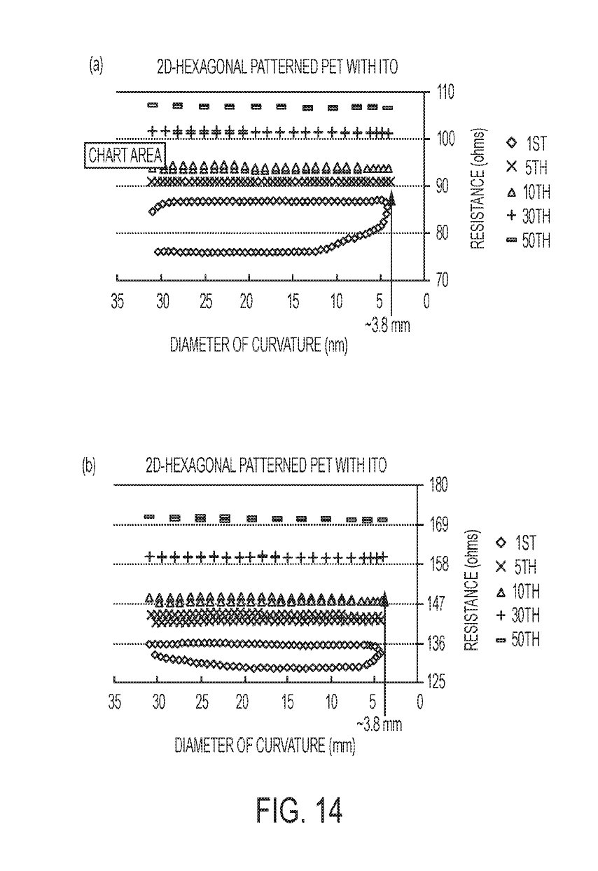

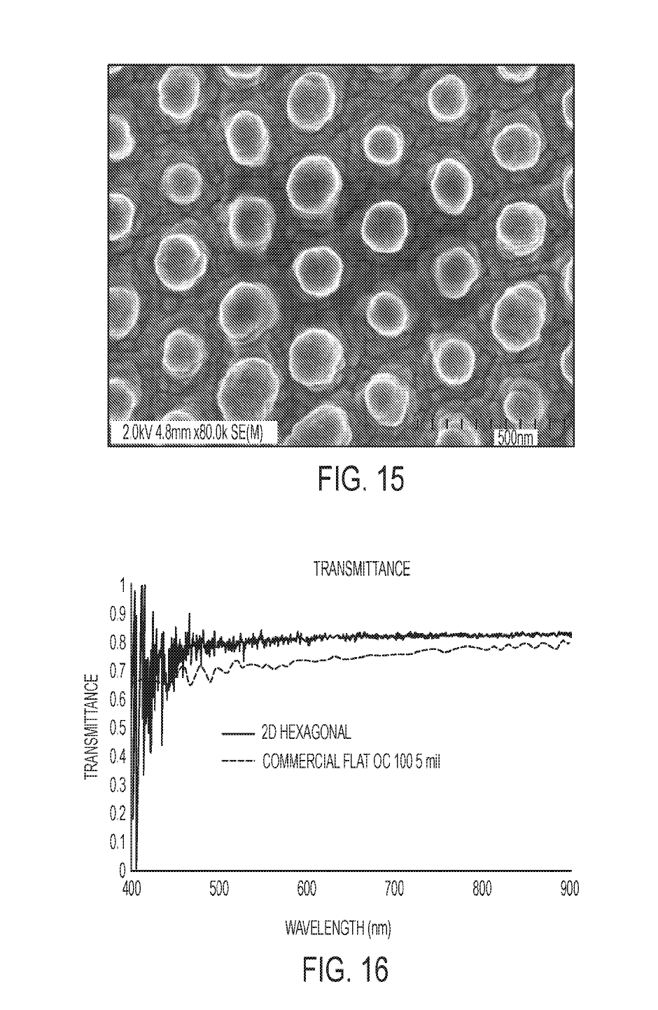

This sample was prepared according to the methods and examples described herein and having a hexagonal array of microstructures as shown on FIG. 15 was tested for bendability in two directions. The resistivity result of these samples is shown on FIG. 14. It can be seen that both in a case when the sample is bended to a bending diameter of 3.8 mm along one pair of parallel ages (FIG. 14a) and the along the other pair of the parallel edges (FIG. 14b), the sample is capable of withstanding at least 50 cycles without substantial structural failure of the film.

FIG. 16 depicts a transmittance comparison of indium tin oxide film deposited on this exemplary 2D (directional)-hexagonal patterned PET substrate with a period of 235 nm and commercially available ITO continuous films. It can be observed that the inventive films have superior transmittance properties when compared with the commercially available films.

### 4. Example 4

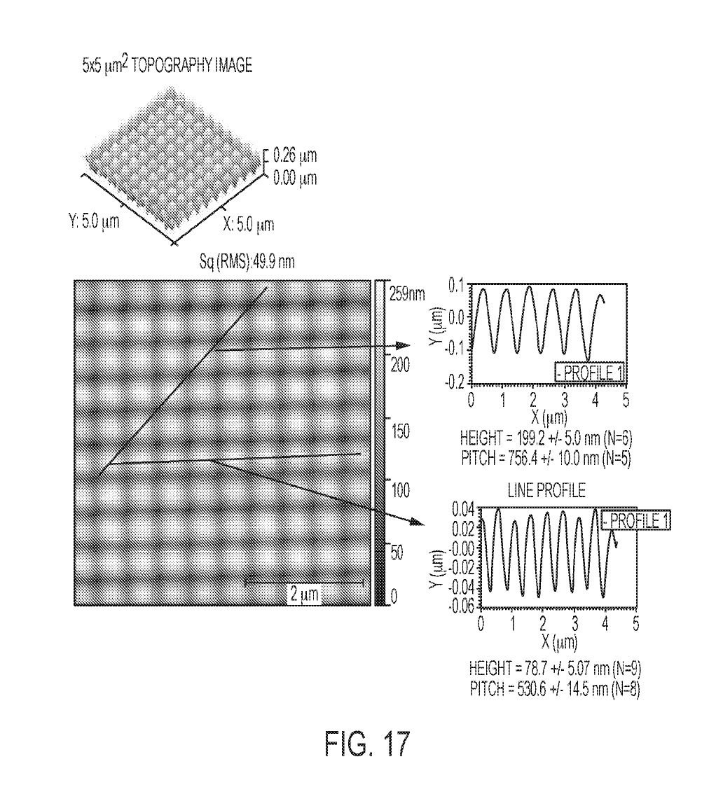

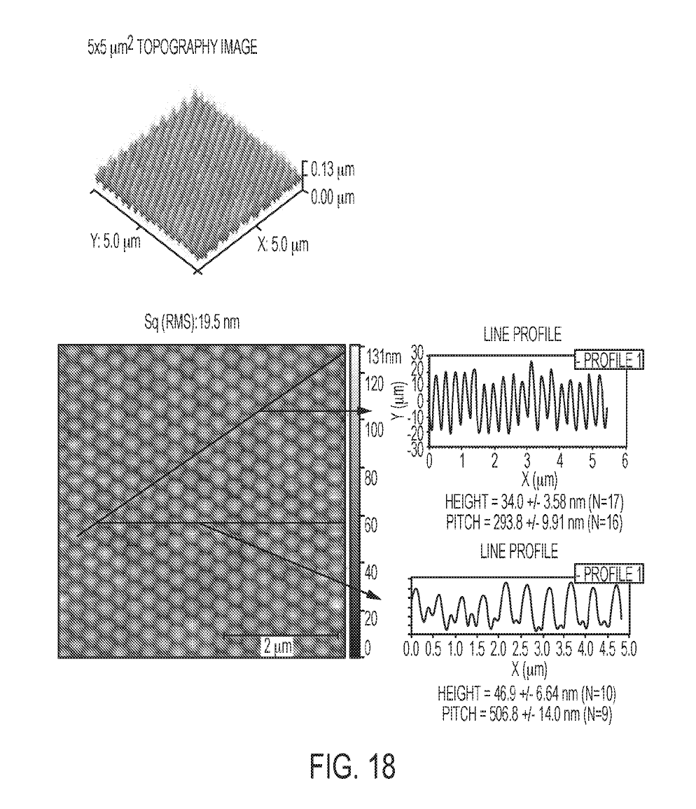

FIGS. 17 and 18 show additional exemplary patterns that can be used for building an article that is bendable in at least one direction, or at least two direction to a being diameter of about 3.8 mm or less, and wherein no substantial structural failure of the film is not expected. FIG. 17 shows a two dimensional square microlens array with an edge pitch of 530 nm and a diagonal pitch of 756 nm. The average height of these exemplary features is 199 nm. FIG. 18 shows a hexagonal array with features heights in the range of 30-50 nm and pitch of 290 nm. It is hypothesized that these patterns are capable of simultaneously ensuring good mechanical (bendability) and optical properties (low haze, low Rb*, low iridescence).

In certain aspects, such two-dimensional patterns can be either flash nanoimprinted using a UV-curable resin (e.g., orthocomp) onto a carrier substrate (such as PET) or directly embossed into such a substrate.

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An article comprising:
a substrate;
a film deposited on the substrate, wherein the article is bendable in at least one direction to a bending diameter of about 3.8 mm or less and wherein no substantial structural failure of the film is observed.

2. The article of claim 1, wherein the substrate is a polymeric substrate.

3. The article of claim 2, wherein the polymeric substrate comprises a polyester, a copolyester, a cellulose ester, a polyolefin, a polyamide, a polyimide, a polystyrene, a polystyrene copolymer, a styrene acrylonitrile copolymer, an acrylontirile butadiene styrene copolymer, a nylon, a poly(methylmethacrylate), an acrylic copolymer, polyphenylene oxide, a poly(phenylene oxide)/polystyrene blend, polyphenylene sulfides, polyetherimide, a polyethersulfone, polyphenylene sulfide/sulfones, polysulfones, a polyetherketone, a polyethylene naphthalene, polycarbonate, poly(ester-carbonates), a cyclic olefin polymer, or any combination thereof

4. The article of claim 3, wherein the polymeric substrate comprises polyethylene-2,6-naphthalate (PEN), polyethylene terephthalate (PET), polyimide polymer (PI), polycarbonate, cellulose triacetate (TAC), polypropylene, or a combination thereof.

5. The article of claim 2, wherein the polymeric substrate comprises a plurality of spatially patterned periodic surface microstructures.

6. The article of claim 5, wherein the plurality of spatially patterned periodic surface microstructures forms a grating-like structure.

7. The article of claim 5, wherein the plurality of spatially patterned periodic surface microstructures comprises dot shaped microstructures.

8. The article of claim 7, wherein the dot shaped microstructures comprise a circular, square, or hexagonal array of microstructures.

9. The article of claim 5, wherein the plurality of spatially patterned periodic surface microstructures have an amplitude from about 0.05 times of a thickness of the film to about 10 times of a thickness of the film.

10. The article of claim 5, wherein the plurality of spatially patterned periodic surface microstructures have a period A from about 100 nm to about 700 nm.

11. The article of claim 1, wherein the plurality of spatially patterned periodic surface microstructures have an amplitude from about 0.5 to about 3 times of a period A value.

12. The article of claim 5, wherein a ratio between a thickness of the film and a period A is from about 5:1 to about 1:5.

13. The article of claim 1, wherein the film comprises a conductive transparent oxide.

14. The article of claim 1, wherein the article has resistivity equal to or less than about 1×10⁴ Ohm×cm.

15. The article of claim 1, wherein the article has a sheet resistance from about 0.01 to about 10,000 Ohm/Sq².

16. The article of claim 1, wherein the article has R_{final}/Rᵢₙᵢₜᵢₐₗ is less than about 1.1, wherein Rᵢₙᵢₜᵢₐₗ is resistivity of the article prior to the bending and R_{final} is the resistivity of the bended article.

17. The article of claim 1, wherein the article is bendable in at least two directions.

18. An article comprising:
a substrate comprising a plurality of spatially patterned periodic surface microstructures; and
a transparent conductive film deposited on the substrate,
wherein the film has at least one point of contact with at least one of the plurality of spatially patterned periodic surface microstructures.

19. The article of claim 18, wherein the article is bendable in at least one direction to a bending diameter of about 3.8 mm or less and wherein no substantial structural failure of the article is observed.

20. The article of claim 18, wherein the substrate is a polymeric substrate.

21. The article of claim 18, wherein the transparent conductive film comprises a transparent conductive oxide film.

22. A method of making an article comprising:
depositing a film on a patterned substrate;
wherein the article is bendable in at least one direction to a bending diameter of about 3.8 mm or less and wherein no substantial structural failure of the film is observed.

23. The method of claim 22, wherein the substrate is a polymeric substrate.

24. The method of claim 23, wherein the patterned polymeric substrate comprises a plurality of spatially patterned periodic surface microstructures.

25. The method of claim 22, wherein the film comprises conductive transparent oxide films.

26. The method of claim 22, wherein the patterned substrate is formed by exposing the substrate to plasma.

27. The method of claim 22, wherein the patterned substrate is formed by molding.

28. The method of claim 22, wherein the patterned polymeric substrate is formed by a chemical etching.

29. The method of claim 22, wherein the patterned substrate is formed by nano-imprinting or a direct embossing.

30. The method of claim 22, wherein the depositing step comprises solution deposition, vacuum evaporation deposition, or a combination thereof.

31. The method of claim 22, wherein the article is bendable in at least two directions.

32. A method comprising:
depositing a transparent conductive film on a patterned substrate;
wherein the patterned substrate comprises a plurality of spatially patterned periodic surface microstructures; and wherein the film has at least one point of contact with at least one of a plurality of spatially patterned periodic surface microstructures.

33. The method of claim 32, wherein the article is bendable in at least one direction to a bending diameter of about 3.8 mm or less and wherein no substantial structural failure of the article is observed.

34. The method of claim 33, wherein the article is bendable in at least two directions.

35. An article comprising:
a polymeric substrate comprising a plurality of spatially patterned periodic surface microstructures, wherein the plurality of spatially patterned periodic surface microstructures forms a grating-like structure;
an indium tin oxide film deposited on the polymeric substrate,
wherein the film has at least one point of contact with at least one of a plurality of spatially patterned periodic surface microstructures, wherein the patterned periodic surface microstructures have a period A from about 100 nm to about 700 nm and amplitude from about to 0.05 times of a thickness of the film to about 10 times of a thickness of the film, and wherein the article is bendable in at least one direction to a bending diameter of about 3.8 mm or less and wherein no substantial structural failure of the article is observed.

36. A method comprising:
forming a patterned polymeric substrate comprising a plurality of spatially patterned periodic surface microstructures; and
depositing an indium tin oxide film on the substrate; wherein the plurality of spatially patterned periodic surface microstructures forms a grating-like structure having a period A from about 10 nm to about 700 nm and amplitude from about to 0.05 times of a thickness of the film to about 10 times of a thickness of the film;
wherein the film has at least one point of contact with at least one of a plurality of spatially patterned periodic microstructures; and wherein the article is bendable in at least one direction to a bending diameter of about 3.8 mm or less and wherein no substantial structural failure of the article is observed.

37. An article comprising:
a polymeric substrate comprising a plurality of spatially patterned periodic surface microstructures, wherein the plurality of spatially patterned periodic surface microstructures forms a dot shaped microstructures comprising a circular, a square, a hexagonal array microstructures, or a combination thereof;
an indium tin oxide film deposited on the polymeric substrate,
wherein the film has at least one point of contact with at least one of a plurality of spatially patterned periodic surface microstructures, wherein the patterned periodic surface microstructures have a period A from about 100 nm to about 700 nm and amplitude from about to 0.05 times of a thickness of the film to about 10 times of a thickness of the film, and wherein the article is bendable in at least one direction to a bending diameter of about 3.8 mm or less and wherein no substantial structural failure of the article is observed.

38. A method comprising:
forming a patterned polymeric substrate comprising a plurality of spatially patterned periodic surface microstructures; and
depositing an indium tin oxide film on the substrate; wherein the plurality of spatially patterned periodic surface microstructures forms a dot shaped microstructures comprising a circular, a square, a hexagonal array microstructures, or a combination thereof, and wherein the plurality of spatially patterned periodic surface microstructures has a period A from about 10 nm to about 700 nm and amplitude from about to 0.05 times of a thickness of the film to about 10 times of a thickness of the film;
wherein the film has at least one point of contact with at least one of a plurality of spatially patterned periodic microstructures; and wherein the article is bendable in at least one direction to a bending diameter of about 3.8 mm or less and wherein no substantial structural failure of the article is observed.
